(19) United States
(12) Patent Application Publication
(10) Pub. No.: US 2026/0324253 A1
(43) Pub. Date: Oct. 15, 2026

(54) DISPLAY DEVICE INCLUDING SEPARATOR BETWEEN CATHODES AND ELECTRONIC DEVICE INCLUDING THE SAME

(71) Applicant: SAMSUNG DISPLAY CO., LTD., YONGIN-SI (KR)

(72) Inventors: JUHOON KANG, Yongin-si (KR); SANG-HEE JANG, Yongin-si (KR); JIYOON KIM, Yongin-si (KR); JIEUN KIM, Yongin-si (KR); Dahwan Lee, Yongin-si (KR)

(21) Appl. No.: 19/413,306

(22) Filed: Dec. 9, 2025

(30) Foreign Application Priority Data
Apr. 15, 2025 (KR) 10-2025-0049103

(51) Int. Cl. H10K 59/80; G09G 3/3233; H10K 59/122; H10K 59/131

(52) U.S. Cl. CPC H10K 59/80521; G09G 3/3233; H10K 59/122; H10K 59/131; G09G 2300/0426; G09G 2300/0819; G09G 2300/0852; G09G 2300/0861; G09G 2320/0233; G09G 2330/021

(57) ABSTRACT

A display device includes a substrate, a first light emitting element in a first emission area, a second light emitting element in a second emission area, and a separator. The first light emitting element includes a first anode electrode electrically connected to a first pixel circuit, a first emission layer on the first anode electrode, and a first cathode electrode on the first emission layer and to which a first low power voltage is applied. The second light emitting element includes a second anode electrode spaced apart from the first anode electrode and electrically connected to a second pixel circuit, a second emission layer on the second anode electrode, and a second cathode electrode on the second emission layer, spaced apart from the second cathode electrode, and to which a second low power voltage is applied. The separator is between the first cathode electrode and the second cathode electrode.

This application claims priority under 35 U.S.C. §119 to Korean Patent Application No. 10-2025-0049103, filed in the Korean Intellectual Property Office on Apr. 15, 2025, the contends of which is hereby incorporated by reference in its entirety.

### TECHNICAL FIELD

The present disclosure relates to a display device and, more specifically, to a display device including a separator between cathodes and an electronic device including the same.

### DISCUSSION OF THE RELATED ART

Flat panel display devices are replacing cathode ray tube display devices due to their lightweight and thin characteristics. Examples of such flat panel display devices include liquid crystal display (LCD) devices and organic light emitting diode (OLED) display devices.

The flat panel display device may include light emitting elements that emit light of different colors, and the magnitudes of driving voltages respectively required to drive the light emitting elements that emit light of different colors may be different from each other. If the same power voltage of the same voltage level is applied to all of pixels included in the display device, the power consumption of the display device may increase as some light emitting elements may be receiving more power than they need.

### SUMMARY

A display device includes a substrate including a first emission area and a second emission area. A first pixel circuit and a second pixel circuit are disposed on the substrate. A first light emitting element is disposed in the first emission area of the substrate. A second light emitting element is disposed in the second emission area of the substrate. A separator is further included. The first light emitting element includes a first anode electrode electrically connected to the first pixel circuit, a first emission layer disposed on the first anode electrode, and a first cathode electrode disposed on the first emission layer and to which a first low power voltage is applied. The second light emitting element includes a second anode electrode spaced apart from the first anode electrode and electrically connected to the second pixel circuit, a second emission layer disposed on the second anode electrode, and a second cathode electrode disposed on the second emission layer, spaced apart from the first cathode electrode, and to which a second low power voltage is applied. The separator is disposed between the first cathode electrode and the second cathode electrode.

The first cathode electrode and the second cathode electrode may be electrically insulated from each other.

The second low power voltage may have a voltage level that is different from that of the first low power voltage.

A same high power voltage may be applied to the first pixel circuit and the second pixel circuit.

The display device may further include a third pixel circuit disposed on the substrate, and a third light emitting element disposed in a third emission area of the substrate. The third light emitting element may include a third anode electrode that is spaced apart from each of the first anode electrode and the second anode electrode and is electrically connected to the third pixel circuit. A third emission layer may be disposed on the third anode electrode, and the second cathode electrode. A first portion of the second cathode electrode may be disposed on the second emission layer, and a second portion of the second cathode electrode may be disposed on the third emission layer.

The first light emitting element may emit blue light, the second light emitting element may emit red light, and the third light emitting element may emit green light.

Each of the first emission area and the second emission area may be provided in plurality. The first cathode electrode may be provided in plurality. In a plan view, the second cathode electrode may be spaced apart from the plurality of first cathode electrodes and may surround the plurality of first cathode electrodes.

In the plan view, each of the plurality of first cathode electrodes may overlap two or more first emission areas of the plurality of first emission areas. In the plan view, the second cathode electrode may overlap all of the second emission areas of the plurality of second emission areas.

In the plan view, each of the plurality of first cathode electrodes may be spaced apart from the second emission areas. In the plan view, the second cathode electrode may be spaced apart from the plurality of first emission areas.

The separator may be provided in plurality. In the plan view, each of the plurality of separators may surround two or more first emission areas of the plurality of first emission areas.

The display device may further include vertical transmission lines spaced apart from each other in a first direction and each extending in a second direction crossing the first direction, and horizontal transmission lines disposed in a different layer from that of the vertical transmission lines, spaced apart from each other in the second direction, and each extending in the first direction. The horizontal transmission lines may include a first horizontal power transmission line to which the first low power voltage is applied, and a second horizontal power transmission line spaced apart from the first horizontal power transmission line and to which the second low power voltage is applied. The vertical transmission lines may include a first vertical power transmission line electrically connected to the first horizontal power transmission line and transmitting the first low power voltage to the first cathode electrodes, and a second vertical power transmission line that is spaced apart from the first vertical power transmission line, electrically connected to the second horizontal power transmission line, and transmitting the second low power voltage to the second cathode electrode.

The plurality of first cathode electrodes may include a first-first cathode electrode corresponding to the first vertical power transmission line, and a first-second cathode electrode corresponding to the second vertical power transmission line. The first-first cathode electrode may be electrically connected to the first vertical power transmission line. The first-second cathode electrode may be electrically connected to the first horizontal power transmission line.

The first-first cathode electrode may directly contact the first vertical power transmission line.

The display device may further include a first connection electrode disposed on a same layer as the second vertical power transmission line. The first connection electrode may be adjacent to the second vertical power transmission line and spaced apart from the second vertical power transmission line in the plan view. The first connection electrode may electrically connect the first horizontal power transmission line and the first-second cathode electrode to one another.

The first-second cathode electrode may directly contact the first connection electrode.

The second cathode electrode may directly contact the second vertical power transmission line.

The display device may further include a second connection electrode disposed on a same layer as that of the first vertical power transmission line. The second connection electrode may be adjacent to the first vertical power transmission line and may be spaced apart from the first vertical power transmission line in the plan view. The second connection electrode may electrically connect the second horizontal power transmission line and the second cathode electrode to one another.

The second cathode electrode may directly contact the second connection electrode.

A display device includes a substrate including first emission areas emitting light of a first color, second emission areas emitting light of a second color, and third emission areas emitting light of a third color. A first cathode electrode is disposed on the substrate. A second cathode electrode is disposed on the substrate. A separator is further included. The first cathode electrode overlaps two or more first emission areas of the first emission areas and is spaced apart from the second emission areas and the third emission areas in a plan view. A first low power voltage is applied to the first cathode electrode. The second cathode electrode overlaps all of the second emission areas and all of the third emission areas and is spaced apart from the first emission areas in the plan view. The second cathode electrode is spaced apart from the first cathode electrode and surrounds the first cathode electrode in the plan view. A second low power voltage having a different voltage level from the first low power voltage is applied to the second cathode electrode. The separator is disposed between the first cathode electrode and the second cathode electrode and surrounds the first cathode electrode in the plan view.

An electronic device includes a display device including light emitting elements and a processor configured to transmit an image data signal and an input control signal to the display device. The display device includes a substrate including a first emission area and a second emission area, a first pixel circuit and a second pixel circuit disposed on the substrate. A first light emitting element is disposed in the first emission area of the substrate. A second light emitting element is disposed in the second emission area of the substrate. A separator is further disposed. The first light emitting element includes a first anode electrode electrically connected to the first pixel circuit, a first emission layer disposed on the first anode electrode, and a first cathode electrode disposed on the first emission layer and to which a first low power voltage is applied. The second light emitting element includes a second anode electrode spaced apart from the first anode electrode and electrically connected to the second pixel circuit, a second emission layer disposed on the second anode electrode, and a second cathode electrode disposed on the second emission layer, spaced apart from the first cathode electrode, and to which a second low power voltage is applied. The separator is disposed between the first cathode electrode and the second cathode electrode.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to an embodiment.

FIGS. 2A, 2B, 2C and 2D, are equivalent circuit diagrams schematically illustrating a pixel according to embodiments.

FIG. 3 is a plan view illustrating emission areas of the display device of FIG. 1.

FIGS. 4, 5, and 6, are plan views illustrating an example of an enlarged portion of the display device of FIG. 1.

FIG. 7 is a cross-sectional view taken along line I-I’ of FIG. 4.

FIG. 8 is an enlarged plan view illustrating an area around a first connection portion of the display device of FIG. 4.

FIG. 9 is a cross-sectional view taken along line II-II’ of FIG. 6.

FIG. 10 is an enlarged plan view illustrating an area around a second connection portion of the display device of FIG. 4.

FIG. 11 is a cross-sectional view taken along line III-III’ of FIG. 10.

FIG. 12 is an enlarged plan view illustrating an area around a third connection portion of the display device of FIG. 4.

FIG. 13 is a cross-sectional view taken along line IV-IV’ of FIG. 12.

FIG. 14 is a plan view illustrating an example of the enlarged portion of the display device of FIG. 1.

FIG. 15 is an enlarged plan view illustrating an area around a fourth connection portion of the display device of FIG. 14.

FIG. 16 is a cross-sectional view taken along line V-V’ of FIG. 15.

FIG. 17 is a block diagram illustrating an electronic device according to an embodiment.

FIG. 18 is a schematic diagram illustrating an electronic device according to various embodiments.

### DETAILED DESCRIPTION

Various example embodiments will be described more fully hereinafter with reference to the accompanying drawings, in which some example embodiments are shown. The present inventive concept may, however, be embodied in many different forms and should not necessarily be construed as limited to the example embodiments set forth herein. Rather, these example embodiments are provided so that this disclosure will be thorough and complete, and will fully convey the scope of the present inventive concept to those skilled in the art. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

In the disclosure, various modifications can be made, various forms can be used, and specific embodiments will be illustrated in the drawings and described in detail in the text. However, this is not necessarily intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not necessarily be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments and is not necessarily intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Hereinafter, embodiments will be described in detail with reference to the accompanying drawings. The same reference numerals may be used for the same components in the drawings, and to the extent that an element is not described in detail with respect to this figure, it may be understood that the element is at least similar to a corresponding element that has been described elsewhere within the present disclosure.

Embodiments of the present disclosure relates to a display device, particularly an OLED display, designed to improve power efficiency by applying different low power voltages to light-emitting elements based on their color requirements. The device includes a substrate divided into multiple emission areas for red, green, and blue light, each having corresponding pixel circuits and light-emitting elements. Each light-emitting element includes an anode electrode, an emission layer, and a cathode electrode. Unlike conventional displays where the same cathode voltage is applied across all pixels, embodiments introduce separate cathode electrodes for groups of emission areas, enabling the application of different low power voltages optimized for specific colors. For example, blue pixels, which generally require a higher driving voltage, receive a distinct voltage from red and green pixels, which share a second voltage level.

To achieve this separation, the device employs a unique structural configuration that includes insulating separators arranged between cathode electrode regions. These separators electrically isolate the cathodes of different color groups and also segment functional layers during deposition, creating distinct electrode regions without cross-connection. This design allows multiple cathode electrodes to coexist within the same display panel while maintaining proper electrical isolation. Transmission lines are strategically placed to deliver the respective low power voltages to the correct cathode electrodes through horizontal and vertical routing, while a common high power voltage is provided to all pixel circuits. This layered and segmented architecture ensures stable voltage supply and prevents electrical interference between adjacent color groups.

As a result, the display significantly reduces overall power consumption compared to conventional designs by tailoring the cathode voltage levels to the actual requirements of each color channel. The approach not only enhances energy efficiency but also maintains image quality and uniform brightness across the panel. Additionally, the design allows integration into various electronic devices without increasing panel thickness or complexity, as the solution leverages existing thin-film transistor structures and organic layer stacking processes. Embodiments thereby address the growing demand for energy-efficient, high-resolution OLED displays used in modern portable electronics.

In this document, the terms, “low power voltage” and “high power voltage” are used. Here, these two terms refer to two distinct voltage levels applied to different parts of the OLED display system. For example, the high power voltage (ELVDD) may be the main driving voltage supplied to the pixel circuits (e.g., the thin-film transistor circuitry). It is applied to control transistors and capacitors within the pixel circuit to generate and regulate current flow for driving the light-emitting element. Thus, the high power voltage may power the active matrix driving components rather than the emission layer itself.

The low power voltage (ELVSS) may be applied to the cathode electrodes of the light-emitting elements. It may determine the electrical potential for the emission layer where electroluminescence occurs. In this disclosure, different low power voltages may be applied to different cathode groups (e.g., blue vs. red/green) because these colors require different forward voltages to achieve proper brightness. By optimizing these voltages individually, the system may reduce unnecessary power consumption.

The high power voltage may have a higher magnitude than the low power voltages. For example, the high power voltage may be within a range of 4V to 10V and the low power voltages may be about 0V and may even be a slightly negative voltage, for example. within a range of 1V to -3V.

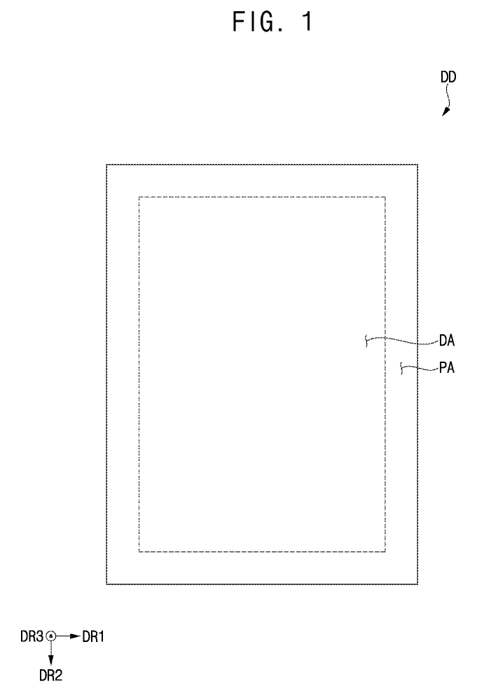

FIG. 1 is a plan view illustrating a display device according to an embodiment.

Referring to FIG. 1, a display device DD may include a display surface for displaying an image. In an embodiment, the display surface may be substantially parallel to a plane defined by a first direction DR1 and a second direction DR2 crossing the first direction DR1. For example, the second direction DR2 may be perpendicular to the first direction DR1. The display device DD may display the image in a third direction DR3 that extends through the display surface. The third direction DR3 may be substantially parallel to a normal direction of the display surface. The third direction DR3 may be perpendicular to each of the first direction DR1 and the second direction DR2. The display surface may correspond to an upper surface (or a front surface) of the display device DD. In an embodiment, the display surface may be curved.

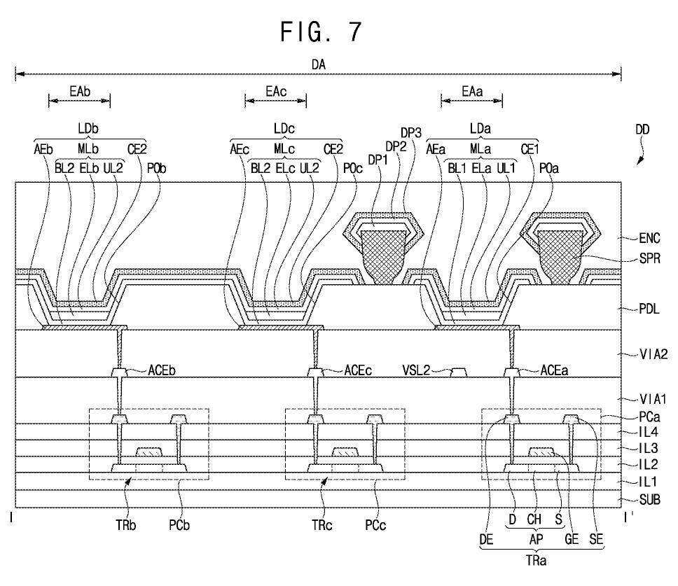

The display device DD (or a substrate SUB of FIG. 7) may include a display area DA for displaying the image and a peripheral area PA located around the display area DA.

A plurality of pixels for generating the image may be disposed in the display area DA. For example, each of the pixels may emit one of red light, green light, and blue light, but the present invention is not necessarily limited thereto.

The peripheral area PA may be located outside the display area DA. For example, the peripheral area PA may surround at least a portion of the display area DA in a plan view. Drivers (e.g., a scan driver, a data driver, or the like) for driving the display area DA, transmission lines for transmitting various signals or voltages to the display area DA, or the like may be disposed in the peripheral area PA.

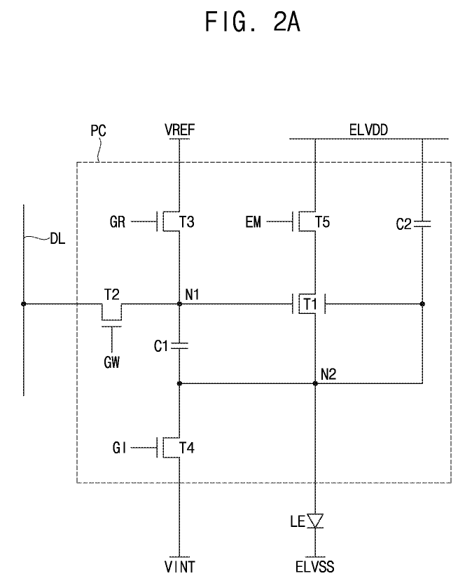

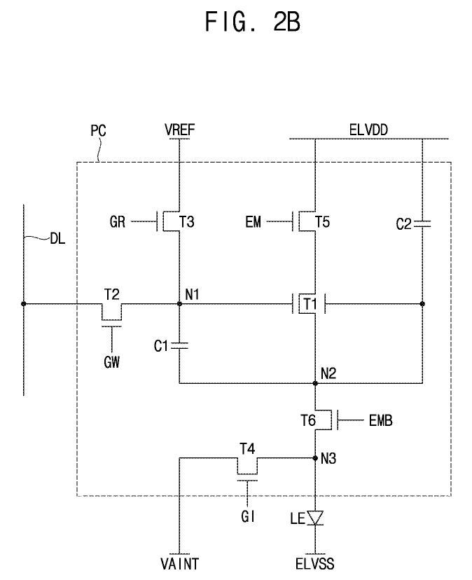

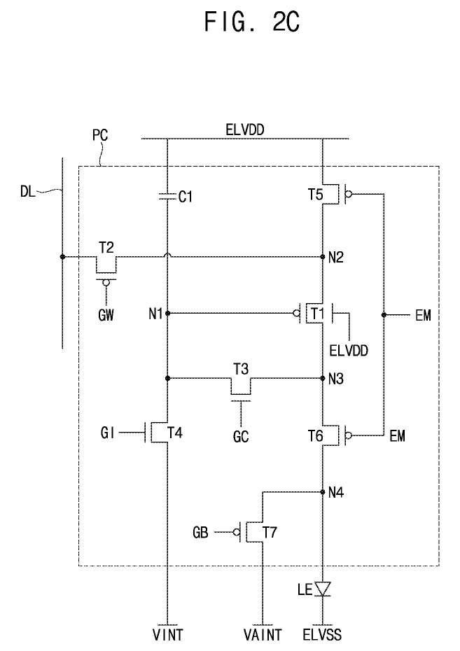

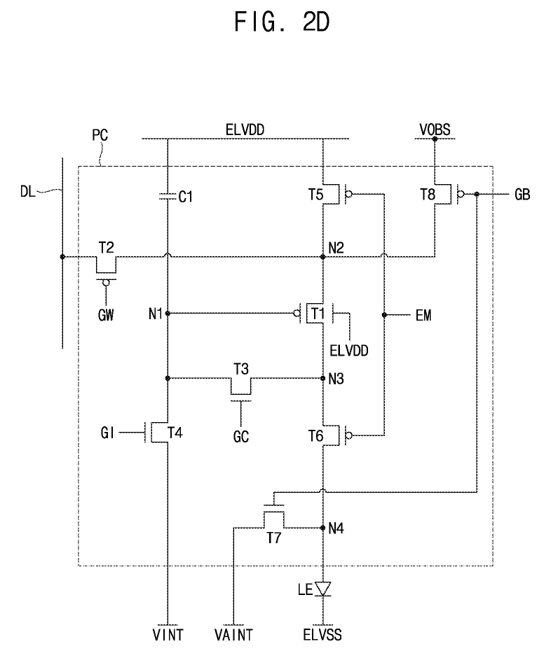

FIGS. 2A, 2B, 2C, and 2D are equivalent circuit diagrams schematically illustrating a pixel according to embodiments.

Each pixel may include a pixel circuit PC and a light emitting element LE. The pixel circuit PC may include at least one thin film transistor and at least one capacitor. The pixel circuit PC may generate a driving current, and may provide the generated driving current to the light emitting element LE. The light emitting element LE may emit light based on the driving current. For example, the light emitting element LE may include an organic light emitting diode, an inorganic light emitting diode, a quantum dot light emitting diode, a micro light emitting diode, or the like.

Referring to FIG. 2A, in an embodiment, the pixel circuit PC may include a first transistor T1, a second transistor T2, a third transistor T3, a fourth transistor T4, a fifth transistor T5, a first capacitor C1, and a second capacitor C2.

The first transistor T1 may include a gate electrode electrically connected to a first node N1, a first electrode, and a second electrode electrically connected to a second node N2. In an embodiment, the first transistor T1 may further include a back gate electrode electrically connected to the second node N2.

The second transistor T2 may include a gate electrode to which a write gate signal GW is applied, a first electrode electrically connected to a data line DL, and a second electrode electrically connected to the first node N1.

The third transistor T3 may include a gate electrode to which a reference gate signal GR is applied, a first electrode to which a reference voltage VREF is applied, and a second electrode electrically connected to the first node N1.

The fourth transistor T4 may include a gate electrode to which an initialization gate signal GI is applied, a first electrode to which an initialization voltage VINT is applied, and a second electrode electrically connected to the second node N2.

The fifth transistor T5 may include a gate electrode to which an emission control signal EM is applied, a first electrode to which a first power voltage ELVDD is applied, and a second electrode electrically connected to the first electrode of the first transistor T1. The first power voltage ELVDD may be a high power voltage.

The first capacitor C1 may include a first electrode electrically connected to the first node N1, and a second electrode electrically connected to the second node N2 and the second electrode of the fourth transistor T4.

The second capacitor C2 may include a first electrode to which the first power voltage ELVDD is applied, and a second electrode electrically connected to the back gate electrode of the first transistor T1 and the second node N2.

In an embodiment, as illustrated in FIG. 2A, each of the first to fifth transistors T1, T2, T3, T4, and T5 may be an NMOS. For example, an active pattern of each of the first to fifth transistors T1, T2, T3, T4, and T5 may include an oxide semiconductor material, but the present invention is not necessarily limited thereto.

The light emitting element LE may include a first electrode electrically connected to the second node N2 and a second electrode to which a second power voltage ELVSS is applied. The first electrode may be an anode electrode, and the second electrode may be a cathode electrode. The second power voltage ELVSS may be a low power voltage.

Referring to FIG. 2B, in an embodiment, the pixel circuit PC may include a first transistor T1, a second transistor T2, a third transistor T3, a fourth transistor T4, a fifth transistor T5, a sixth transistor T6, a first capacitor C1, and a second capacitor C2.

The first transistor T1 may include a gate electrode electrically connected to a first node N1, a first electrode, and a second electrode electrically connected to a second node N2. In an embodiment, the first transistor T1 may further include a back gate electrode electrically connected to the second node N2.

The second transistor T2 may include a gate electrode to which a write gate signal GW is applied, a first electrode electrically connected to a data line DL, and a second electrode electrically connected to the first node N1.

The third transistor T3 may include a gate electrode to which a reference gate signal GR is applied, a first electrode to which a reference voltage VREF is applied, and a second electrode electrically connected to the first node N1.

The fourth transistor T4 may include a gate electrode to which an initialization gate signal GI is applied, a first electrode to which an initialization voltage VAINT is applied, and a second electrode electrically connected to a third node N3.

The fifth transistor T5 may include a gate electrode to which a first emission control signal EM is applied, a first electrode to which a first power voltage ELVDD is applied, and a second electrode electrically connected to the first electrode of the first transistor T1. The first power voltage ELVDD may be a high power voltage.

The sixth transistor T6 may include a gate electrode to which a second emission control signal EMB is applied, a first electrode electrically connected to the second node N2, and a second electrode electrically connected to the third node N3.

The first capacitor C1 may include a first electrode electrically connected to the first node N1 and a second electrode electrically connected to the second node N2.

The second capacitor C2 may include a first electrode to which the first power voltage ELVDD is applied, and a second electrode electrically connected to the back gate electrode of the first transistor T1 and the second node N2.

In an embodiment, as illustrated in FIG. 2B, each of the first to sixth transistors T1, T2, T3, T4, T5, and T6 may be an NMOS. For example, an active pattern of each of the first to sixth transistors T1, T2, T3, T4, T5, and T6 may include an oxide semiconductor material, but the present invention is not necessarily limited thereto.

The light emitting element LE may include a first electrode electrically connected to the third node N3 and a second electrode to which a second power voltage ELVSS is applied. The first electrode may be an anode electrode, and the second electrode may be a cathode electrode. The second power voltage ELVSS may be a low power voltage.

Referring to FIG. 2C, in an embodiment, the pixel circuit PC may include a first transistor T1, a second transistor T2, a third transistor T3, a fourth transistor T4, a fifth transistor T5, a sixth transistor T6, a seventh transistor T7, and a first capacitor C1.

The first transistor T1 may include a gate electrode electrically connected to a first node N1, a first electrode electrically connected to a second node N2, and a second electrode electrically connected to a third node N3. In an embodiment, the first transistor T1 may further include a back gate electrode to which a first power voltage ELVDD is applied. The first power voltage ELVDD may be a high power voltage.

The second transistor T2 may include a gate electrode to which a write gate signal GW is applied, a first electrode electrically connected to a data line DL, and a second electrode electrically connected to the second node N2.

The third transistor T3 may include a gate electrode to which a compensation gate signal GC is applied, a first electrode electrically connected to the first node N1, and a second electrode electrically connected to the third node N3.

The fourth transistor T4 may include a gate electrode to which an initialization gate signal GI is applied, a first electrode to which a first initialization voltage VINT is applied, and a second electrode electrically connected to the first node N1 and the first electrode of the third transistor T3.

The fifth transistor T5 may include a gate electrode to which an emission control signal EM is applied, a first electrode to which the first power voltage ELVDD is applied, and a second electrode electrically connected to the second node N2.

The sixth transistor T6 may include a gate electrode to which the emission control signal EM is applied, a first electrode electrically connected to the third node N3, and a second electrode electrically connected to a fourth node N4.

The seventh transistor T7 may include a gate electrode to which a bias gate signal GB is applied, a first electrode to which a second initialization voltage VAINT is applied, and a second electrode electrically connected to the fourth node N4.

The first capacitor C1 may include a first electrode to which the first power voltage ELVDD is applied and a second electrode electrically connected to the first node N1.

In an embodiment, as illustrated in FIG. 2C, each of the first transistor T1, the second transistor T2, the fifth transistor T5, the sixth transistor T6, and the seventh transistor T7 may be a P-type metal-oxide-semiconductor (PMOS), and each of the third transistor T3 and the fourth transistor T4 may be an N-type metal-oxide-semiconductor (NMOS). For example, an active pattern of each of the first transistor T1, the second transistor T2, the fifth transistor T5, the sixth transistor T6, and the seventh transistor T7 may include a silicon semiconductor material, and an active pattern of each of the third transistor T3 and the fourth transistor T4 may include an oxide semiconductor material, but the present invention is not necessarily limited thereto.

The light emitting element LE may include a first electrode electrically connected to the fourth node N4 and a second electrode to which a second power voltage ELVSS is applied. The first electrode may be an anode electrode, and the second electrode may be a cathode electrode. The second power voltage ELVSS may be a low power voltage.

Referring to FIG. 2D, in an embodiment, the pixel circuit PC may include a first transistor T1, a second transistor T2, a third transistor T3, a fourth transistor T4, a fifth transistor T5, a sixth transistor T6, a seventh transistor T7, an eighth transistor T8, and a first capacitor C1.

The first transistor T1 may include a gate electrode electrically connected to a first node N1, a first electrode electrically connected to a second node N2, and a second electrode electrically connected to a third node N3. In an embodiment, the first transistor T1 may further include a back gate electrode to which a first power voltage ELVDD is applied. The first power voltage ELVDD may be a high power voltage.

The second transistor T2 may include a gate electrode to which a write gate signal GW is applied, a first electrode electrically connected to a data line DL, and a second electrode electrically connected to the second node N2.

The third transistor T3 may include a gate electrode to which a compensation gate signal GC is applied, a first electrode electrically connected to the first node N1, and a second electrode electrically connected to the third node N3.

The fourth transistor T4 may include a gate electrode to which an initialization gate signal GI is applied, a first electrode to which a first initialization voltage VINT is applied, and a second electrode electrically connected to the first node N1 and the first electrode of the third transistor T3.

The fifth transistor T5 may include a gate electrode to which an emission control signal EM is applied, a first electrode to which the first power voltage ELVDD is applied, and a second electrode electrically connected to the second node N2.

The sixth transistor T6 may include a gate electrode to which the emission control signal EM is applied, a first electrode electrically connected to the third node N3, and a second electrode electrically connected to a fourth node N4.

The seventh transistor T7 may include a gate electrode to which a bias gate signal GB is applied, a first electrode to which a second initialization voltage VAINT is applied, and a second electrode electrically connected to the fourth node N4.

The eighth transistor T8 may include a gate electrode to which the bias gate signal GB is applied, a first electrode to which an on-bias voltage VOBS is applied, and a second electrode electrically connected to the second node N2.

The first capacitor C1 may include a first electrode to which the first power voltage ELVDD is applied and a second electrode electrically connected to the first node N1.

In an embodiment, as illustrated in FIG. 2D, each of the first transistor T1, the second transistor T2, the fifth transistor T5, the sixth transistor T6, the seventh transistor T7, and the eighth transistor T8 may be a PMOS, and each of the third transistor T3 and the fourth transistor T4 may be an NMOS. For example, an active pattern of each of the first transistor T1, the second transistor T2, the fifth transistor T5, the sixth transistor T6, the seventh transistor T7, and the eighth transistor T8 may include a silicon semiconductor material, and an active pattern of each of the third transistor T3 and the fourth transistor T4 may include an oxide semiconductor material, but the present invention is not necessarily limited thereto.

The light emitting element LE may include a first electrode electrically connected to the fourth node N4 and a second electrode to which a second power voltage ELVSS is applied. The first electrode may be an anode electrode, and the second electrode may be a cathode electrode. The second power voltage ELVSS may be a low power voltage.

Although the pixel circuit PC, according to embodiments, has been described above with reference to FIGS. 2A to 2D, this is an example and the present invention is not necessarily limited thereto, and the structure of the pixel circuit PC may be variously changed.

Thus, the display device may include a display surface, which may be flat or curved, oriented along two perpendicular directions with images viewed in a third normal direction. The display device may include a display area with pixels that generate images using red, green, or blue light and a surrounding peripheral area containing drivers and transmission lines for controlling these pixels. Each pixel features a pixel circuit with multiple transistors and capacitors that control a light-emitting element, which operates with a high power voltage for driving and a low power voltage for emission, and these circuits can vary in configuration, using NMOS, PMOS, or mixed transistor types depending on the design.

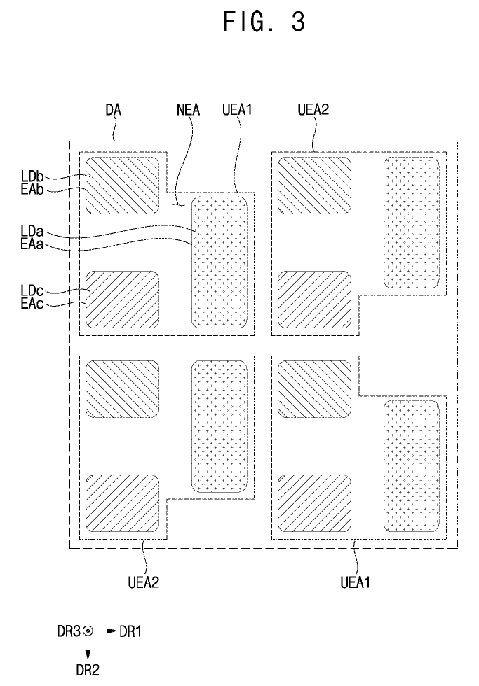

FIG. 3 is a plan view illustrating emission areas of the display device of FIG. 1.

Referring to FIG. 3, in an embodiment, the display area DA may include first emission areas EAa, second emission areas EAb, third emission areas EAc, and a non-emission area NEA.

The first to third emission areas EAa, EAb, and EAc may be spaced apart from each other in a plan view. Light emitting elements may be disposed in the first to third emission areas EAa, EAb, and EAc, respectively. The first to third emission areas EAa, EAb, and EAc may be areas where light is emitted from the light emitting elements. For example, a first light emitting element LDa may be disposed in the first emission area EAa, and the first emission area EAa may be an area where light is emitted from the first light emitting element LDa. A second light emitting element LDb may be disposed in the second emission area EAb, and the second emission area EAb may be an area where light is emitted from the second light emitting element LDb. A third light emitting element LDc may be disposed in the third emission area EAc, and the third emission area EAc may be an area where light is emitted from the third light emitting element LDc.

In an embodiment, the first emission area EAa, the second emission area EAb, and the third emission area EAc may emit light of different colors. For example, the first emission area EAa may emit blue light, the second emission area EAb may emit red light, and the third emission area EAc may emit green light. However, this is an example and the present invention is not necessarily limited thereto.

In an embodiment, the first light emitting element LDa, the second light emitting element LDb, and the third light emitting element LDc may emit light of different colors. For example, the first light emitting element LDa may emit blue light, the second light emitting element LDb may emit red light, and the third light emitting element LDc may emit green light. However, this is an example and the present invention is not necessarily limited thereto.

Light emitting elements might not be disposed in the non-emission area NEA. The non-emission area NEA may be an area where light is not emitted from. The non-emission area NEA may be disposed between the first to third emission areas EAa, EAb, and EAc. For example, the non-emission area NEA may surround each of the first to third emission areas EAa, EAb, and EAc in a plan view.

In an embodiment, the first emission area EAa, the second emission area EAb, and the third emission area EAc, which are adjacent to each other, may form one unit emission area (a first unit emission area UEA1 or a second unit emission area UEA2). In an embodiment, as illustrated in FIG. 3, in each unit emission area, the first to third emission areas EAa, EAb, and EAc may be disposed in an S-stripe type. For example, in each unit emission area, the first emission area EAa may be located in the first direction DR1 from the second emission area EAb and the third emission area EAc, and the third emission area EAc may be located in the second direction DR2 from the second emission area EAb. However, this is an example and the present invention is not necessarily limited thereto, and the arrangement of the first to third emission areas EAa, EAb, and EAc may be variously changed according to embodiments.

In an embodiment, the first unit emission areas UEA1 and the second unit emission areas UEA2 may be defined in a matrix form in the first direction DR1 and the second direction DR2. Although FIG. 3 illustrates four unit emission areas, the unit emission areas may be defined in a matrix form in the first direction DR1 and the second direction DR2 in the display area DA.

In an embodiment, the first unit emission area UEA1 and the second unit emission area UEA2 may be distinguished based on the arrangement of the first to third light emitting elements LDa, LDb, and LDc (or the arrangement of the first to third emission areas EAa, EAb, and EAc). For example, the arrangement of the first to third light emitting elements LDa, LDb, and LDc (or the first to third emission areas EAa, EAb, and EAc) may be the same for each first unit emission area UEA1, and the arrangement of the first to third light emitting elements LDa, LDb, and LDc (or the first to third emission areas EAa, EAb, and EAc) may be the same for each second unit emission area UEA2.

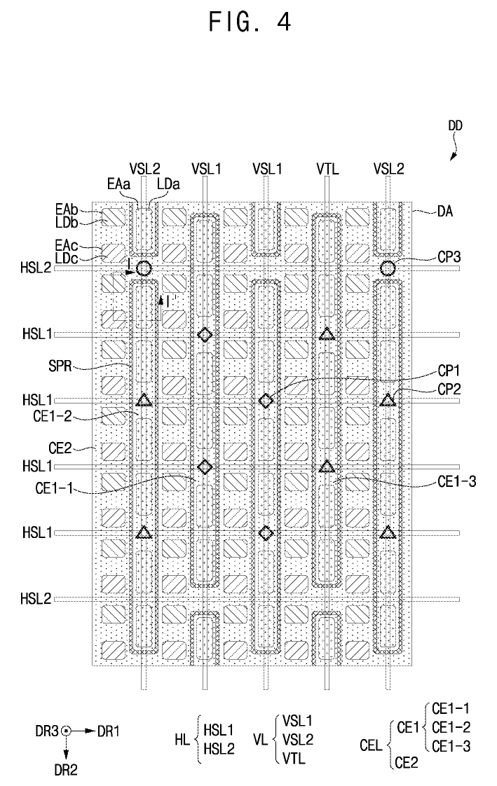

As illustrated in FIGS. 3 and 4, in an embodiment, the first unit emission areas UEA1 and the second emission areas UEA2 may be alternately disposed in the first direction DR1 (i.e., a row direction) and the second direction DR2 (i.e., a column direction). However, the present invention is not necessarily limited thereto, and the number of different unit emission areas included in the display device DD or the arrangement of the unit emission areas may be variously changed according to embodiments.

FIGS. 4 to 6 are plan views illustrating an example of an enlarged portion of the display device of FIG. 1. FIG. 7 is a cross-sectional view taken along line I-I’ of FIG. 4.

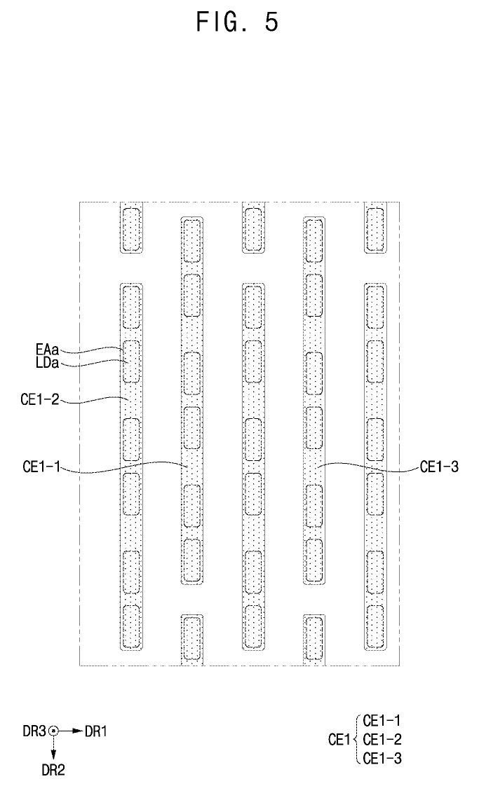

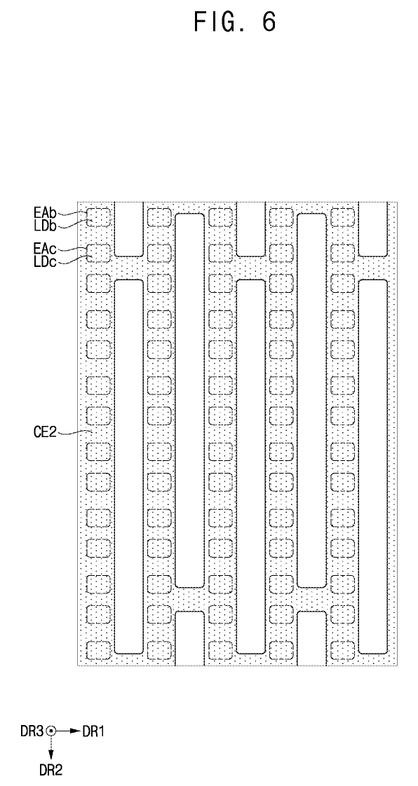

FIG. 4 illustrates a portion of the display area DA of the display device DD of FIG. 1. FIG. 5 illustrates first cathode electrodes CE1 of FIG. 4, and FIG. 6 illustrates a second cathode electrode CE2 of FIG. 4. Hereinafter, a planar structure and a cross-sectional structure of the display area DA of the display device DD, according to an embodiment, will be described in detail with reference to FIGS. 4 to 7.

Referring to FIGS. 4 to 7, in an embodiment, the display device DD may include a substrate SUB, first to third pixel circuits PCa, PCb, and PCc, first to fourth insulating layers IL1, IL2, IL3, and IL4, first and second via insulating layers VIA1 and VIA2, first to third anode connection electrodes ACEa, ACEb, and ACEc, horizontal transmission lines HL, vertical transmission lines VL, first to third light emitting elements LDa, LDb, and LDc, a pixel defining layer PDL, separators SPR, and an encapsulation layer ENC.

The substrate SUB may form a base of the display device DD. In an embodiment, examples of materials that can be used as the substrate SUB may include glass, quartz, silicon, polymers, or the like. These may be used alone or in combination with each other. In addition, the substrate SUB may have a single layer structure or a multi-layer structure in which multiple layers including different materials are stacked.

The first insulating layer IL1 may be disposed on the substrate SUB. In an embodiment, the first insulating layer IL1 may include an inorganic insulating material. Examples of the insulating material that can be used as the first insulating layer IL1 may include silicon oxide (SiOₓ), silicon nitride (SiNₓ), silicon oxynitride (SiOₓN_{y}), or the like. These may be used alone or in combination with each other. The first insulating layer IL1 may have a single layer structure or a multi-layer structure in which a plurality of insulating layers are stacked.

The first to third pixel circuits PCa, PCb, and PCc may be disposed on the display area DA on the first insulating layer IL1. The first to third pixel circuits PCa, PCb, and PCc may be electrically connected to the first to third light emitting elements LDa, LDb, and LDc, respectively. In an embodiment, the same high power voltage may be applied to the first to third pixel circuits PCa, PCb, and PCc.

Each of the first to third pixel circuits PCa, PCb, and PCc may include at least one thin film transistor and at least one capacitor. For example, each of the first to third pixel circuits PCa, PCb, and PCc may be one of the pixel circuits PC of FIGS. 2A to 2D. For convenience of description, a first transistor TRa included in the first pixel circuit PCa, a second transistor TRb included in the second pixel circuit PCb, and a third transistor TRc included in the third pixel circuit PCc are illustrated in FIG. 7. For example, the first transistor TRa, the second transistor TRb, and the third transistor TRc may be one of the first transistor T1 of FIG. 2A, the sixth transistor T6 of FIG. 2B, the sixth transistor T6 of FIG. 2C, and the sixth transistor T6 of FIG. 2D.

In an embodiment, the first transistor TRa may include an active pattern AP, a gate electrode GE, a first contact electrode SE, and a second contact electrode DE.

The active pattern AP may be disposed on the first insulating layer IL1. The active pattern AP may include an oxide semiconductor material, a silicon semiconductor material, and/or an organic semiconductor material. The active pattern AP may include a first contact area S, a second contact area D, and a channel area CH between the first contact area S and the second contact area D. The first contact area S and the second contact area D may have higher conductivity than the channel area CH.

In an embodiment, the active pattern AP may include an oxide semiconductor material. Examples of the oxide semiconductor material that can be used as the active pattern AP may include indium gallium zinc oxide (IGZO), zinc tin oxide (ZTO), indium tin zinc oxide (ITZO), or the like. These may be used alone or in combination with each other. However, the present invention is not necessarily limited thereto, and the active pattern AP may include a silicon semiconductor material.

The second insulating layer IL2 may be disposed on the first insulating layer IL1. The second insulating layer IL2 may cover the active pattern AP. In an embodiment, the second insulating layer IL2 may include an inorganic insulating material. The second insulating layer IL2 may have a single layer structure or a multi-layer structure in which a plurality of insulating layers are stacked.

The gate electrode GE may be disposed on the second insulating layer IL2. The gate electrode GE may overlap the channel area CH of the active pattern AP. The gate electrode GE may include a conductive material, such as a metal, an alloy, a conductive metal oxide, a conductive metal nitride, a transparent conductive oxide or the like. The gate electrode GE may have a single layer structure or a multilayer structure in which a plurality of conductive layers are stacked.

The third insulating layer IL3 may be disposed on the second insulating layer IL2. The third insulating layer IL3 may cover the gate electrode GE. In an embodiment, the third insulating layer IL3 may include an inorganic insulating material. The third insulating layer IL3 may have a single layer structure or a multilayer structure in which a plurality of insulating layers are stacked.

In an embodiment, a capacitor electrode may be disposed on the third insulating layer IL3. The capacitor electrode and a conductive pattern (e.g., the gate electrode GE), which is disposed between the second insulating layer IL2 and the third insulating layer IL3 and overlaps the capacitor electrode, may form the capacitor.

The fourth insulating layer IL4 may be disposed on the third insulating layer IL3. The fourth insulating layer IL4 may cover the capacitor electrode. In an embodiment, the fourth insulating layer IL4 may include an inorganic insulating material. The fourth insulating layer IL4 may have a single layer structure or a multi-layer structure in which a plurality of insulating layers are stacked.

The first and second contact electrodes SE and DE may be disposed on the fourth insulating layer IL4. The first contact electrode SE may contact the first contact area S1 of the active pattern AP, and the second contact electrode DE may contact the second contact area D1 of the active pattern AP. Each of the first and second contact electrodes SE and DE may include a conductive material, such as a metal, an alloy, a conductive metal oxide, a conductive metal nitride, a transparent conductive oxide, or the like. Each of the first and second contact electrodes SE and DE may have a single layer structure or a multi-layer structure in which a plurality of conductive layers are stacked.

In an embodiment, the display device DD may further include a lower conductive pattern disposed between the substrate SUB and the first insulating layer IL1 and overlapping the active pattern AP. For example, the lower conductive pattern may be electrically connected to one of the gate electrode GE, the first contact electrode SE, and the second contact electrode DE.

The description of the first transistor TRa described above may be substantially equally applied to the second transistor TRb included in the second pixel circuit PCb and the third transistor TRc included in the third pixel circuit PCc.

The first via insulation layer VIA1 may be disposed on the fourth insulation layer IL4. The first via insulation layer VIA1 may cover the first and second contact electrodes SE and DE. In an embodiment, the first via insulation layer VIA1 may include an organic insulation material. Examples of the organic insulation material that can be used as the first via insulation layer VIA1 may include a photoresist, a polyacryl-based resin, a polyimide-based resin, a polyamide-based resin, a siloxane-based resin, an acrylic resin, an epoxy-based resin, or the like. These may be used alone or in combination with each other. The first via insulation layer VIA1 may have a single layer structure or a multi-layer structure in which a plurality of insulation layers are stacked.

The first to third anode connection electrodes ACEa, ACEb, and ACEc may be disposed on the first via insulating layer VIA1. The first anode connection electrode ACEa may electrically connect the first pixel circuit PCa and the first light emitting element LDa. The first anode connection electrode ACEa may contact the first contact electrode SE or the second contact electrode DE of the first transistor TRa of the first pixel circuit PCa. The second anode connection electrode ACEb may electrically connect the second pixel circuit PCb and the second light emitting element LDb. The second anode connection electrode ACEb may contact the first contact electrode or the second contact electrode of the second transistor TRb of the second pixel circuit PCb. The third anode connection electrode ACEc may electrically connect the third pixel circuit PCc and the third light emitting element LDc. The third anode connection electrode ACEc may contact the first contact electrode or the second contact electrode of the third transistor TRc of the third pixel circuit PCc.

Each of the first to third anode connection electrodes ACEa, ACEb, and ACEc may include a conductive material, such as a metal, an alloy, a conductive metal oxide, a conductive metal nitride, a transparent conductive oxide, or the like. Each of the first to third anode connection electrodes ACEa, ACEb, and ACEc may have a single layer structure or a multilayer structure in which a plurality of conductive layers are stacked.

The second via insulation layer VIA2 may be disposed on the first via insulation layer VIA1. The second via insulation layer VIA2 may cover the first to third anode connection electrodes ACEa, ACEb, and ACEc. In an embodiment, the second via insulation layer VIA2 may include an organic insulation material. The second via insulation layer VIA2 may have a single layer structure or a multilayer structure in which a plurality of insulation layers are stacked.

In an embodiment, as illustrated in FIG. 4, the horizontal transmission lines HL may generally extend in the first direction DR1, and may be spaced apart from each other in the second direction DR2. The vertical transmission lines VL may generally extend in the second direction DR2, and may be spaced apart from each other in the first direction DR1. The horizontal transmission lines HL and the vertical transmission lines VL may cross each other.

The horizontal transmission lines HL may be disposed in a same layer as each other. The vertical transmission lines VL may be disposed in a same layer as each other. The vertical transmission lines VL may be disposed in a different layer from the horizontal transmission lines HL.

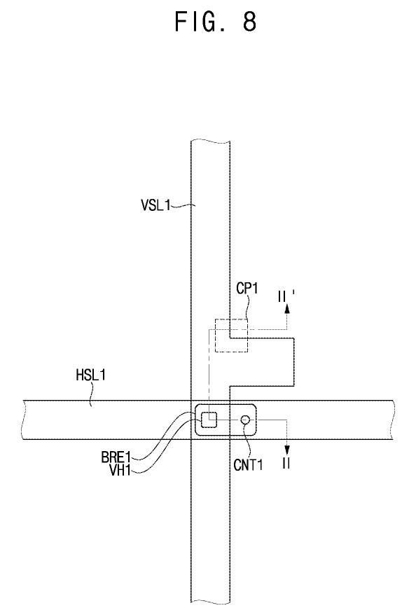

In an embodiment, the horizontal transmission lines HL may be disposed between the substrate SUB and the first insulating layer IL1, and the vertical transmission lines VL may be disposed between the first via insulating layer VIA1 and the second via insulating layer VIA2 (see FIG. 8). For example, the horizontal transmission lines HL and the lower conductive pattern may be disposed in a same layer as each other, and may be substantially formed simultaneously with each other. The vertical transmission lines VL and the first to third anode connection electrodes ACEa, ACEb, and ACEc may be disposed in a same layer as each other, and may be substantially formed simultaneously with each other. However, this is an example and the present invention is not necessarily limited thereto, and each of the horizontal transmission lines HL and the vertical transmission lines VL may be disposed in a same layer as another conductive layers (e.g., the gate electrode GE, the capacitor electrode, the first and second contact electrodes SE and DE, or the like) between the substrate SUB and the first to third light emitting elements LDa, LDb, and LDc.

In an embodiment, as illustrated in FIG. 4, the horizontal transmission lines HL and the vertical transmission lines VL may correspond one-to-one with the unit emission areas. For example, one horizontal transmission line HL and one vertical transmission line VL may correspond to one unit emission area. However, this is an example and the present invention is not necessarily limited thereto, and the number of horizontal transmission lines HL and the number of vertical transmission lines VL disposed to correspond to one unit emission area may be variously changed.

In an embodiment, the horizontal transmission lines HL may include a first horizontal power transmission line HSL1 and a second horizontal power transmission line HSL2. The first horizontal power transmission line HSL1 and the second horizontal power transmission line HSL2 might not be electrically connected to each other (or may be electrically insulated from each other).

In an embodiment, the vertical transmission lines VL may include a first vertical power transmission line VSL1, a second vertical power transmission line VSL2, and a voltage transmission line VTL. The first vertical power transmission line VSL1, the second vertical power transmission line VSL2, and the voltage transmission line VTL might not be electrically connected to each other (or may be electrically insulated from each other).

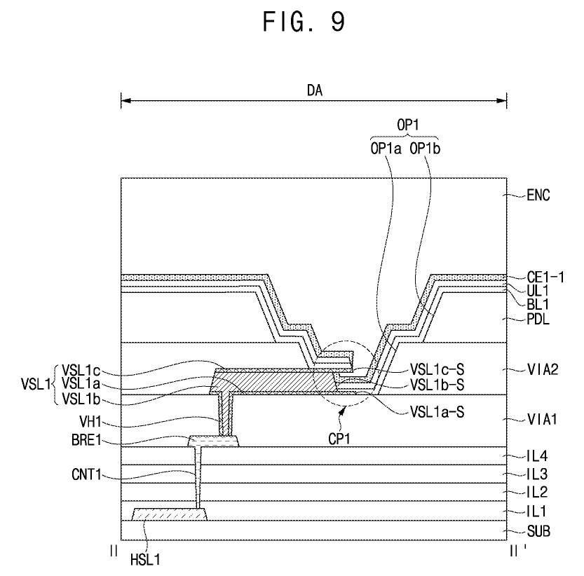

In an embodiment, the first vertical power transmission line VSL1 may be electrically connected to the first horizontal power transmission line HSL1 (see FIG. 9). A first low power voltage may be applied to the first vertical power transmission line VSL1 and the first horizontal power transmission line HSL1. For example, the first vertical power transmission line VSL1 or the first horizontal power transmission line HSL1 may be electrically connected to a first power supply line in the peripheral area PA (see FIG. 1), and may receive the first low power voltage from the first power supply line. In an embodiment, the first vertical power transmission line VSL1 and the first horizontal power transmission line HSL1 may transmit the first low power voltage to the first light emitting elements LDa. This will be described in detail later.

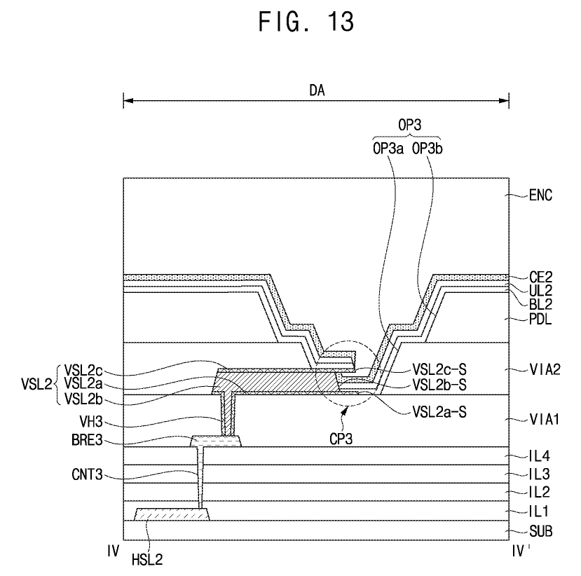

In an embodiment, the second vertical power transmission line VSL2 may be electrically connected to the second horizontal power transmission line HSL2 (see FIG. 13). A second low power voltage may be applied to the second vertical power transmission line VSL2 and the second horizontal power transmission line HSL2. In an embodiment, the second low power voltage may have a different voltage level from the first low power voltage. For example, the second vertical power transmission line VSL2 or the second horizontal power transmission line HSL2 may be electrically connected to a second power supply line in the peripheral area PA (see FIG. 1), and may receive the second low power voltage from the second power supply line. In an embodiment, the second vertical power transmission line VSL2 and the second horizontal power transmission line HSL2 may transmit the second low power voltage to the second and third light emitting elements LDb and LDc. This will be described in detail later.

A voltage (e.g., the high power voltage, the initialization voltage, the reference voltage, or the like) required for driving the display area DA may be applied to the voltage transmission line VTL.

The arrangement of the horizontal transmission lines HL and the vertical transmission lines VL illustrated in FIG. 4 is an example, and the present invention is not necessarily limited thereto.

As illustrated in FIG. 7, the first to third light emitting elements LDa, LDb, and LDc may be disposed on the second via insulating layer VIA2. The first to third light emitting elements LDa, LDb, and LDc may be disposed in the first to third emission areas EAa, EAb, and EAc, respectively.

The first light emitting element LDa may include a first anode electrode AEa, a first intermediate layer MLa, and a first cathode electrode CE1. The first intermediate layer MLa may include a first lower functional layer BL1, a first emission layer ELa, and a first upper functional layer UL1. For example, the first emission layer ELa may include a first emission material that emits blue light.

The second light emitting element LDb may include a second anode electrode AEb, a second intermediate layer MLb, and a second cathode electrode CE2. The second intermediate layer MLb may include a second lower functional layer BL2, a second emission layer ELb, and a second upper functional layer UL2. For example, the second emission layer ELb may include a second emission material that emits red light.

The third light emitting element LDc may include a third anode electrode AEc, a third intermediate layer MLc, and the second cathode electrode CE2. The third intermediate layer MLc may include the second lower functional layer BL2, a third emission layer ELc, and the second upper functional layer UL2. For example, the third emission layer ELc may include a third emission material that emits green light.

In an embodiment, the second light emitting element LDb and the third emitting element LDc may share the second cathode electrode CE2. For example, as illustrated in FIG. 6, the second cathode electrode CE2 may be entirely formed on the second emission areas EAb and the third emission areas EAc. A portion of the second cathode electrode CE2 may function as the cathode of the second light emitting element LDb, and another portion of the second cathode electrode CE2 may function as the cathode of the third light emitting element LDc. In addition, the second light emitting element LDb and the third light emitting element LDc may share the second lower functional layer BL2 and the second upper functional layer UL2.

The first to third anode electrodes AEa, AEb, and AEc may be disposed on the second via insulating layer VIA2. The first to third anode electrodes AEa, AEb, and AEc may be disposed in the first to third emission areas EAa, EAb, and EAc, respectively. Each of the first to third anode electrodes AEa, AEb, and AEc may include a conductive material, such as a metal, an alloy, a conductive metal oxide, a conductive metal nitride, a transparent conductive oxide, or the like. Each of the first to third anode electrodes AEa, AEb, and AEc may have a single layer structure or a multi-layer structure in which a plurality of conductive layers are stacked.

The first anode electrode AEa may contact the first anode connection electrode ACEa. Accordingly, the first anode electrode AEa may be electrically connected to the first pixel circuit PCa through the first anode connection electrode ACEa.

The second anode electrode AEb may contact the second anode connection electrode ACEb. Accordingly, the second anode electrode AEb may be electrically connected to the second pixel circuit PCb through the second anode connection electrode ACEb.

The third anode electrode AEc may contact the third anode connection electrode ACEc. Accordingly, the third anode electrode AEc may be electrically connected to the third pixel circuit PCc through the third anode connection electrode ACEc.

The pixel defining layer PDL may be disposed on the second via insulating layer VIA2. The pixel defining layer PDL may cover a peripheral portion of each of the first to third anode electrodes AEa, AEb, and AEc. The pixel defining layer PDL may define a first pixel opening POa that exposes a central portion of the first anode electrode AEa, a second pixel opening POb that exposes a central portion of the second anode electrode AEb, and a third pixel opening POc that exposes a central portion of the third anode electrode AEc. The first emission area EAa may be defined by the first pixel opening POa, the second emission area EAb may be defined by the second pixel opening POb, and the third emission area EAc may be defined by the third pixel opening POc.

In an embodiment, the pixel defining layer PDL may include an organic insulating material. For example, the pixel defining layer PDL may include a photosensitive resin. In an embodiment, the pixel defining layer PDL may further include a light blocking material, such as a black dye, a pigment, carbon black, or the like.

The separators SPR may be disposed on the pixel defining layer PDL. As illustrated in FIG. 4, the separators SPR may be disposed in the non-emission area NEA in a plan view. The separators SPR might not overlap the first to third emission areas EAa, EAb, and EAc in a plan view. In an embodiment, the separators SPR may be spaced apart from each other in a plan view.

In an embodiment, each of the separators SPR may surround at least one of the first emission area EAa in a plan view. For example, each of the separators SPR may have a closed-loop shape in a plan view. For example, each of the separators SPR may surround two or more first emission areas EAa, which are adjacent to each other in the second direction DR2, in a plan view. For example, one separator SPR may correspond to two or more first emission areas EAa. The separators SPR might not surround the second and third emission areas EAb and EAc in a plan view.

All of the first emission areas EAa may be surrounded by the separators SPR in a plan view. Each of the first emission areas EAa may be surrounded by one of the separators SPR in a plan view. For example, in a plan view, each of the first emission areas EAa may be located inside the corresponding separator SPR, and the second and third emission areas EAb and EAc may be located outside the separators SPR.

As illustrated in FIGS. 4 to 7, the separators SPR may separate (or disconnect) a cathode electrode layer CEL into the first cathode electrodes CE1 and the second cathode electrode CE2. In addition, the separators SPR may separate (or disconnect) a lower functional layer into the first lower functional layers BL1 and the second lower functional layer BL2, and may separate (or disconnect) an upper functional layer into the first upper functional layers UL1 and the second upper functional layer UL2. This will be described in detail later.

In an embodiment, each of the separators SPR may include an organic electrically insulating material. For example, each of the separators SPR may include a photosensitive resin.

In an embodiment, as illustrated in FIG. 7, a width of an upper portion of the separator SPR may be greater than a width of a lower portion of the separator SPR. For example, a side surface of the separator SPR connecting an upper surface of the separator SPR and a lower surface of the separator SPR may be a reverse-tapered sloped surface. For example, the side surface of the separator SPR may have multiple reverse-tapered sloped surfaces. For example, the separator SPR may have a double reverse-tapered structure.

The first intermediate layer MLa may be disposed on the first anode electrode AEa and the pixel defining layer PDL. The second intermediate layer MLb may be disposed on the second anode electrode AEb and the pixel defining layer PDL. The third intermediate layer MLc may be disposed on the third anode electrode AEc and the pixel defining layer PDL.

In an embodiment, the first emission layer ELa may be disposed on the first anode electrode AEa in the first pixel opening POa. The second emission layer ELb may be disposed on the second anode electrode AEb in the second pixel opening POb. The third emission layer ELc may be disposed on the third anode electrode AEc in the third pixel opening POc.

Each of the first lower functional layer BL1, the second lower functional layer BL2, the first upper functional layer UL1, and the second upper functional layer UL2 may include organic materials. The first lower functional layer BL1 and the second lower functional layer BL2 may have a same material and a same layer structure, and the first upper functional layer UL1 and the second upper functional layer UL2 may have a same material and a same layer structure. The first lower functional layer BL1 and the second lower functional layer BL2 may be substantially simultaneously formed with each other, and the first upper functional layer UL1 and the second upper functional layer UL2 may be substantially simultaneously formed with each other. For example, each of the first lower functional layer BL1 and the second lower functional layer BL2 may include a hole injection layer, a hole transport layer, or the like, and each of the first upper functional layer UL1 and the second upper functional layer UL2 may include an electron transport layer, an electron injection layer, or the like.

A shadow area where it is difficult to deposit the lower functional layer may exist around the separator SPR having reverse-tapered sloped surfaces. Accordingly, in the shadow area and/or around the shadow area, the lower functional layer may have a structure separated (or disconnected) by the separator SPR. For example, the lower functional layer may be separated (or disconnected) into the first lower functional layers BL1 and the second lower functional layer BL2, which are spaced apart from each other, by the separator SPR.

A shadow area where it is difficult to deposit the upper functional layer may exist around the separator SPR having reverse-tapered sloped surfaces. Accordingly, in the shadow area and/or around the shadow area, the upper functional layer may have a structure separated (or disconnected) by the separator SPR. For example, the upper functional layer may be separated (or disconnected) into the first upper functional layers UL1 and the second upper functional layer UL2, which are spaced apart from each other, by the separator SPR.

In an embodiment, the first lower functional layers BL1 and the first upper functional layers UL1 may have substantially the same planar shape as the first cathode electrodes CE1 of FIG. 5. The second lower functional layer BL2 and the second upper functional layer UL2 may have substantially the same planar shape as the second cathode electrode CE2 of FIG. 6. For example, each of the first lower functional layers BL1 and each of the first upper functional layers UL1 may be entirely disposed inside the corresponding separator SPR in a plan view. The second lower functional layer BL2 and the second upper functional layer UL2 may be entirely disposed outside the separators SPR in a plan view.

The cathode electrode layer CEL may be disposed on the first to third intermediate layers MLa, MLb, and MLc. The cathode electrode layer CEL may include a conductive material, such as a metal, an alloy, a conductive metal oxide, a conductive metal nitride, a transparent conductive oxide, or the like. In an embodiment, the cathode electrode layer CEL may have a single layer structure. However, the present invention is not necessarily limited thereto. In an embodiment, the cathode electrode layer CEL may have a multi-layer structure in which a plurality of conductive layers are stacked. For example, the cathode electrode layer CEL may have a two-layer structure in which a first-first sub-electrode layer including a metal material and a first-second sub-electrode layer including a transparent conductive oxide are stacked on each other.

A shadow area where it is difficult to deposit the cathode electrode layer CEL may exist around the separator SPR having reverse-tapered sloped surfaces. Accordingly, in the shadow area and/or around the shadow area, the cathode electrode layer CEL have a structure separated (or disconnected) by the separator SPR. For example, the cathode electrode layer CEL may be separated (or disconnected) into the first cathode electrodes CE1 and the second cathode electrode CE2, which are spaced apart from each other, by the separator SPR.

As illustrated in FIGS. 4 to 6, the first cathode electrodes CE1 and the second cathode electrode CE2 may be spaced apart from each other in a plan view. The first cathode electrodes CE1 and the second cathode electrode CE2 might not be electrically connected to each other (or may be electrically insulated from each other). The first cathode electrodes CE1 and the second cathode electrode CE2 may have a same material and a same layer structure. The first cathode electrodes CE1 and the second cathode electrode CE2 may be substantially simultaneously formed with each other.

In an embodiment, each of the first cathode electrodes CE1 may be entirely disposed inside the corresponding separator SPR in a plan view. Each of the separators SPR may be disposed between the corresponding first cathode electrode CE1 and the second cathode electrode CE2 in a plan view.

In an embodiment, in a plan view, the second cathode electrode CE2 may be spaced apart from the first cathode electrodes CE1, and may surround the first cathode electrodes CE1. In an embodiment, the second cathode electrode CE2 may be entirely disposed on outside the separators SPR in a plan view. For example, the second cathode electrode CE2 may have a generally mesh shape in a plan view.

In an embodiment, when each of the separators SPR surrounds two or more first emission areas EAa adjacent in the second direction DR2 in a plan view, each of the first cathode electrodes CE1 may overlap two or more first emission areas EAa adjacent in the second direction DR2 in a plan view. For example, one first cathode electrode CE1 may correspond to two or more first emission areas EAa.

Each of the first cathode electrodes CE1 might not overlap the second emission areas EAb and the third emission areas EAc in a plan view. For example, each of the first cathode electrodes CE1 may be spaced apart from the second emission areas EAb and the third emission areas EAc in a plan view.

In an embodiment, the second cathode electrode CE2 may overlap all of the second emission areas EAb and all of the third emission areas EAc in a plan view.

The second cathode electrode CE2 might not overlap the first emission areas EAa in a plan view. For example, the second cathode electrode CE2 may be spaced apart from the first emission areas EAa in a plan view.

The first low power voltage may be applied to the first cathode electrodes CE1. Each first cathode electrode CE1 may be disposed on the first emission layer ELa and may function as the cathode of the first light emitting element LDa.

The second low power voltage may be applied to the second cathode electrode CE2. A portion of the second cathode electrode CE2 may be disposed on the second emission layer ELb and may function as the cathode of the second light emitting element LDb. Another portion of the second cathode electrode CE2 may be disposed on the third emission layer ELc and may function as the cathode of the third light emitting element LDc.

Each of the first cathode electrodes CE1 may receive the first low power voltage through the corresponding first horizontal power transmission line HSL1 and the corresponding first vertical power transmission line VSL1.

In an embodiment, the first cathode electrodes CE1 may include a first-first cathode electrode CE1-1, a first-second cathode electrode CE1-2, and a first-third cathode electrode CE1-3. As illustrated in FIG. 4, the first-first cathode electrode CE1-1 may be an electrode disposed to correspond to (e.g., to overlap) the first vertical power transmission line VSL1 among the vertical transmission lines VL, the first-second cathode electrode CE1-2 may be an electrode disposed to correspond to (e.g., to overlap) the second vertical power transmission line VSL2 among the vertical transmission lines VL, and the first-third cathode electrode CE1-3 may be an electrode disposed to correspond to (e.g., to overlap) the voltage transmission line VTL among the vertical transmission lines VL.

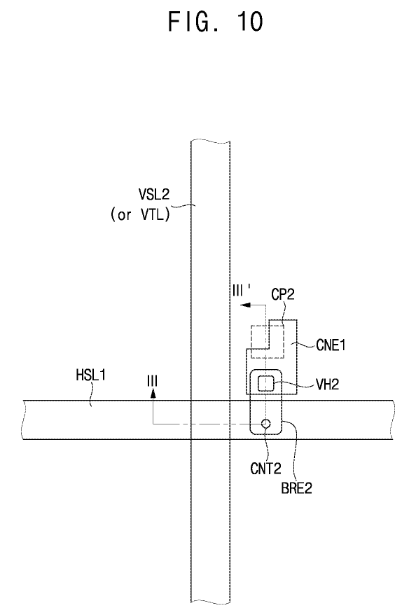

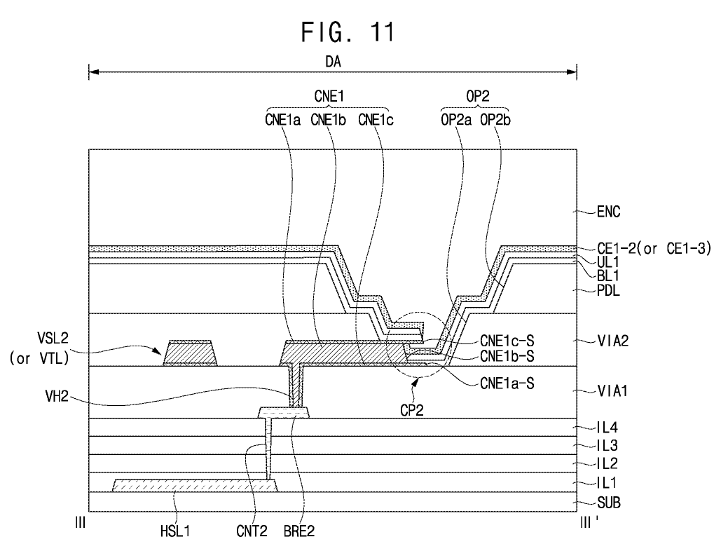

The first-first cathode electrode CE1-1 may be electrically connected to a first connection portion CP1 of the first vertical power transmission line VSL1 (see FIGS. 8 and 9). Each of the first-second cathode electrode CE1-2 and the first-third cathode electrode CE1-3 may be electrically connected to a second connection portion CP2 of a corresponding first connection electrode CNE1, and the first connection electrode CNE1 may be electrically connected to the first horizontal power transmission line HSL1 through a second bridge electrode BRE2 (see FIGS. 10 and 11).

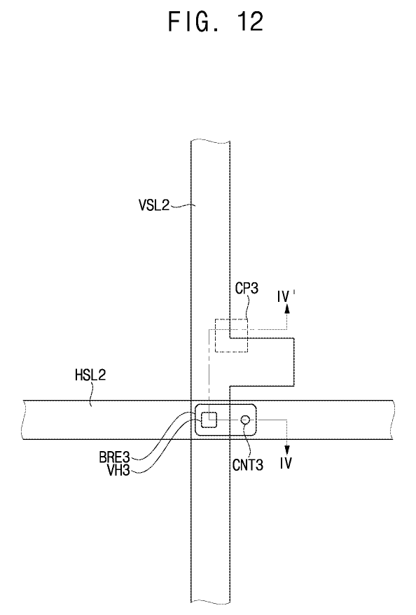

The second cathode electrode CE2 may receive the second low power voltage through the second horizontal power transmission line HSL2 and the second vertical power transmission line VSL2. The second cathode electrode CE2 may be electrically connected to a third connection portion CP3 of the second vertical power transmission line VSL2 (see FIGS. 12 and 13). For example, the second cathode electrode CE2 may be electrically connected to a plurality of second vertical power transmission lines VSL2.

The connection structure of the first cathode electrodes CE1, the first vertical power transmission line VSL1, and the first horizontal power transmission line HSL1, and the connection structure of the second cathode electrode CE2, the second vertical power transmission line VSL2, and the second horizontal power transmission line HSL2 will be described in detail later with reference to FIGS. 8 to 13.

In an embodiment, first to third dummy patterns DP1, DP2, and DP3 may be disposed on the separator SPR. For example, the first dummy pattern DP1 may be formed by the lower functional layer that is separated (or disconnected) by the separator SPR, the second dummy pattern DP2 may be formed by the upper functional layer that is separated (or disconnected) by the separator SPR, and the third dummy pattern DP3 may be formed by the cathode electrode layer CEL that is separated (or disconnected) by the separator SPR. For example, the first dummy pattern DP1 may be formed by the same process as the first lower functional layers BL1 and the second lower functional layer BL2, the second dummy pattern DP2 may be formed by the same process as the first upper functional layers UL1 and the second upper functional layer UL2, and the third dummy pattern DP3 may be formed by the same process as the first cathode electrodes CE1 and the second cathode electrode CE2. In an embodiment, at least some of the first to third dummy patterns DP1, DP2, and DP3 may be omitted.

The encapsulation layer ENC may be disposed on the first cathode electrodes CE1 and the second cathode electrode CE2. The encapsulation layer ENC may entirely cover the separator SPR, the first cathode electrodes CE1, the second cathode electrode CE2, and the first to third dummy patterns DP1, DP2, and DP3. In an embodiment, the encapsulation layer ENC may include a first inorganic encapsulation layer including an inorganic insulating material, an organic encapsulation layer disposed on the first inorganic encapsulation layer and including an organic insulating material, and a second inorganic encapsulation layer disposed on the organic encapsulation layer and including an inorganic insulating material.

In an embodiment, a touch sensing layer may be disposed on the encapsulation layer ENC. For example, the touch sensing layer may include multiple touch electrode arrays for detecting a user's input in a capacitive manner, a touch pad portion, and multiple touch wires electrically connecting the touch pad portion and the touch electrode arrays. However, the present invention is not necessarily limited thereto. In an embodiment, the touch sensing layer may be omitted.

The magnitudes of driving voltages respectively required to drive the first to third light emitting elements LDa, LDb, and LDc that emit light of different colors may be different from each other. For example, the magnitude of the driving voltage required to drive the second light emitting element LDb that emits red light may be similar to the magnitude of the driving voltage required to drive the third light emitting element LDc that emits green light, but a difference between the magnitude of the driving voltage required to drive the first light emitting element LDa that emits blue light and the magnitude of the driving voltage required to drive the second light emitting element LDb that emits red light (or, the magnitude of the driving voltage required to drive the third light emitting element LDc that emits green light) may be relatively large. In this case, if the same high power voltage of the same voltage level and the same low power voltage of the same voltage level are applied to all of the pixels (e.g., blue pixels, red pixels, and green pixels), the power consumption of the display device DD may increase.

In the display device DD, according to embodiments, low power voltages having different voltage levels may be applied to at least some of the first to third light emitting elements LDa, LDb, and LDc that emit light of different colors. For example, the first low power voltage may be applied to the first cathode electrode CE1 of the first light emitting element LDa (e.g., a blue light emitting element), and the second low power voltage having a different voltage level from the first low power voltage may be applied to the second cathode electrode CE2 of the second light emitting element LDb (e.g., a red light emitting element) and the third light emitting element LDc (e.g., a green light emitting element), which require a similar magnitude of driving voltage. For example, in the display device DD according to embodiments, compared to the case in which the same low power voltage of the same voltage level is applied to all of the pixels (e.g., blue pixels, red pixels, and green pixels), low power voltages optimized for each pixel may be applied to the light emitting elements. Accordingly, the power consumption of the display device DD may be reduced.

Thus, the display area may be divided into first, second, and third emission areas, each corresponding to a light-emitting element that produces blue, red, or green light, and these are grouped into unit emission areas arranged in an S-stripe pattern. Separators may be placed in non-emission areas to electrically isolate functional layers, creating separate cathode electrodes for blue pixels and for red and green pixels. This structure allows the application of different low power voltages to different color groups, optimizing voltage supply for each color and significantly reducing power consumption compared to designs that apply the same voltage to all pixel types.

FIG. 8 is an enlarged plan view illustrating an area around a first connection portion of the display device of FIG. 4. FIG. 9 is a cross-sectional view taken along line II-II’ of FIG. 6.

Hereinafter, an example of the connection structure of the first-first cathode electrode CE1-1, the first vertical power transmission line VSL1, and the first horizontal power transmission line HSL1 will be described in detail with reference to FIGS. 8 and 9.

Referring to FIGS. 4, 8, and 9, in an embodiment, the first-first cathode electrode CE1-1 may be electrically connected to the first connection portion CP1 of the corresponding first vertical power transmission line VSL1.

In an embodiment, the first vertical power transmission line VSL1 may have a multi-layer structure in which a plurality of conductive layers are stacked. For example, the first vertical power transmission line VSL1 may include a first conductive layer VSL1a, a second conductive layer VSL1b, and a third conductive layer VSL1c that are sequentially stacked.

In an embodiment, the first conductive layer VSL1a may include a metal and/or a transparent conductive oxide. Examples of the metal that can be used as the first conductive layer VSL1a may include titanium (Ti), molybdenum (Mo), or the like. Examples of the transparent conductive oxide that can be used as the first conductive layer VSL1a may include indium tin oxide (ITO), indium zinc oxide (IZO), zinc oxide (ZnOₓ), indium oxide (InOₓ), indium gallium oxide (IGO), aluminum zinc oxide (AZO), or the like. The first conductive layer VSL1a may have a relatively small thickness compared to the second conductive layer VSL1b.

The second conductive layer VSL1b may include a different material from the first conductive layer VSL1a. For example, the second conductive layer VSL1b may include a different metal from the first conductive layer VSL1a. Examples of the metal that can be used as the second conductive layer VSL1b may include aluminum (Al), copper (Cu), or the like. The second conductive layer VSL1b may have a relatively large thickness compared to the first conductive layer VSL1a.

The third conductive layer VSL1c may include a different material from the second conductive layer VSL1b. For example, the third conductive layer VSL1c may include a different metal and/or transparent conductive oxide from the second conductive layer VSL1b. Examples of the metal that can be used as the third conductive layer VSL1c may include Ti, Mo, or the like. Examples of the transparent conductive oxide that can be used as the third conductive layer VSL1c may include ITO, IZO, ZnOₓ, InOₓ, IGO, AZO, or the like. The third conductive layer VSL1c may have a relatively small thickness compared to the second conductive layer VSL1b.

In an embodiment, the first conductive layer VSL1a and the third conductive layer VSL1c may include the same material. However, the present invention is not necessarily limited thereto.

A side surface VSL1b-S of the second conductive layer VSL1b may be recessed in a direction toward a center of the first vertical power transmission line VSL1 from a side surface VSL1a-S of the first conductive layer VSL1a and a side surface VSL1c-S of the third conductive layer VSL1c. For example, the side surface VSL1a-S of the first conductive layer VSL1a and the side surface VSL1c-S of the third conductive layer VSL1c may protrude outward from the side surface VSL1b-S of the second conductive layer VSL1b. Accordingly, the first connection portion CP1 of the first vertical power transmission line VSL1 may have a tip portion due to a portion of the third conductive layer VSL1c protruding compared to the second conductive layer VSL1b. For example, based on the same etching process, when etching the second conductive layer VSL1b using an etching material having a high etch rate for the second conductive layer VSL1b compared to the first conductive layer VSL1a and the third conductive layer VSL1c, the first vertical power transmission line VSL1 may be formed to have the tip portion.

FIG. 9 illustrates that the first vertical power transmission line VSL1 has a three-layer structure in which the first to third conductive layers VSL1a, VSL1b, and VSL1c are stacked. However, the present invention is not necessarily limited thereto, and the first vertical power transmission line VSL1 may have a two-layer structure in which the second conductive layer VSL1b and the third conductive layer VSL1c are stacked. For example, the first conductive layer VSL1a may be omitted.

The second via insulating layer VIA2 may define a first-first sub-opening OP1a that exposes a portion of the first vertical power transmission line VSL1. For example, the first-first sub-opening OP1a may expose the tip portion of the first connection portion CP1 of the first vertical power transmission line VSL1.

The pixel defining layer PDL may define a first-second sub-opening OP1b corresponding to the first-first sub-opening OP1a. The first-second sub-opening OP1b may be located on the first-first sub-opening OP1a, and the first-first sub-opening OP1a and the first-second sub-opening OP1b may be spatially connected to each other. For example, the first-first sub-opening OP1a and the first-second sub-opening OP1b may be spatially connected to define a first opening OP1, and the first opening OP1 may expose the tip portion of the first connection portion CP1 of the first vertical power transmission line VSL1.

The lower functional layer, the upper functional layer, and the cathode electrode layer CEL may also be separated (or disconnected) by the tip portion of the first connection portion CP1 of the first vertical power transmission line VSL1. Because the lower functional layer and the upper functional layer are separated (or disconnected) by the tip portion of the first connection portion CP1 of the first vertical power transmission line VSL1, the lower functional layer and the upper functional layer may expose at least a portion of the side surface VSL1b-S of the second conductive layer VSL1b of the first vertical power transmission line VSL1. Accordingly, the first-first cathode electrode CE1-1 may contact the side surface VSL1b-S of the second conductive layer VSL1b of the first vertical power transmission line VSL1.

The first-first cathode electrode CE1-1 may be electrically connected to the corresponding first vertical power transmission line VSL1. For example, the first-first cathode electrode CE1-1 may contact the side surface VSL1b-S of the second conductive layer VSL1b of the first vertical power transmission line VSL1. For example, in case that a deposition angle of a deposition process for forming the cathode electrode layer CEL is greater than a deposition angle of a deposition process for forming the lower functional layer and a deposition angle of a deposition process for forming the upper functional layer, the cathode electrode layer CEL (e.g., the first-first cathode electrode CE1-1) may be formed to overlap the discontinuity in the lower functional layer (e.g., the first lower functional layer BL1) and the discontinuity in the upper functional layer (e.g., the first upper functional layer UL1) separated by the tip portion and to contact the side surface VSL1b-S of the second conductive layer VSL1b of the first vertical power transmission line VSL1. For example, the first-first cathode electrode CE1-1 may directly contact the first vertical power transmission line VSL1. Accordingly, the first-first cathode electrode CE1-1 may be electrically connected to the first vertical power transmission line VSL1.

In an embodiment, the first vertical power transmission line VSL1 may be electrically connected to the first horizontal power transmission line HSL1 through a first bridge electrode BRE1. As illustrated in FIG. 8, the first bridge electrode BRE1 may be disposed at a crossing area where the first vertical power transmission line VSL1 and the first horizontal power transmission line HSL1 cross each other in a plan view.

In an embodiment, the first bridge electrode BRE1 may be disposed on the same layer as the first and second contact electrodes SE and DE of FIG. 7. The first bridge electrode BRE1 may contact the first horizontal power transmission line HSL1 through a first contact hole CNT1 that penetrates the first to fourth insulating layers IL1, IL2, IL3, and IL4. The first vertical power transmission line VSL1 may contact the first bridge electrode BRE1 through a first via hole VH1 that penetrates the first via insulating layer VIA1. However, this is an example and the present invention is not necessarily limited thereto.

Accordingly, the first-first cathode electrode CE1-1 may be electrically connected to the first vertical power transmission line VSL1 and the first horizontal power transmission line HSL1. Therefore, the first-first cathode electrode CE1-1 may receive the first low power voltage through the first vertical power transmission line VSL1 and the first horizontal power transmission line HSL1.

In an embodiment, as illustrated in FIG. 4, the first-first cathode electrode CE1-1 may be electrically connected to two or more first connection portions CP1. Accordingly, it is possible to reduce defects (e.g., dark spots, luminance degradation, or the like) of the first light emitting element LDa due to poor connection between the first-first cathode electrode CE1-1 and the first vertical power transmission line VSL1.

FIG. 10 is an enlarged plan view illustrating an area around a second connection portion of the display device of FIG. 4. FIG. 11 is a cross-sectional view taken along line III-III’ of FIG. 10.

Hereinafter, an example of the connection structure of the first-second cathode electrode CE1-2 (or the first-third cathode electrode CE1-3) and the first horizontal power transmission line HSL1 will be described in detail. with reference to FIGS. 10 and 11.

Referring to FIGS. 4, 10 and 11, in an embodiment, the first-second cathode electrode CE1-2 (or the first-third cathode electrode CE1-3) may be electrically connected to a second connection portion CP2 of the first connection electrode CNE1.

In an embodiment, the first connection electrode CNE1 may be disposed on the same layer as the second vertical power transmission line VSL2 (or the voltage transmission line VTL). As illustrated in FIG. 10, in a plan view, the first connection electrode CNE1 may be adjacent to the second vertical power transmission line VSL2 (or the voltage transmission line VTL), and may be spaced apart from the second vertical power transmission line VSL2 (or the voltage transmission line VTL). The first connection electrode CNE1 may electrically connect the first horizontal power transmission line HSL1 and the first-second cathode electrode CE1-2 (or the first-third cathode electrode CE1-3). The first connection electrode CNE1 might not be electrically connected to (or may be electrically insulated from) the second vertical power transmission line VSL2 (or the voltage transmission line VTL).

In an embodiment, the first connection electrode CNE1 may have a multi-layer structure in which a plurality of conductive layers are stacked. For example, the first connection electrode CNE1 may include a first conductive layer CNE1a, a second conductive layer CNE1b, and a third conductive layer CNE1c that are sequentially stacked. For example, the first connection electrode CNE1 may have substantially the same layer structure as the first vertical power transmission line VSL1 described above with reference to FIGS. 8 and 9. Therefore, repeated description will be omitted or simplified.

A side surface CNE1b-S of the second conductive layer CNE1b may be recessed in a direction toward a center of the first connection electrode CNE1 from a side surface CNE1a-S of the first conductive layer CNE1a and a side surface CNE1c-S of the third conductive layer CNE1c. For example, the side surface CNE1a-S of the first conductive layer CNE1a and the side surface CNE1c-S of the third conductive layer CNE1c may protrude outward from the side surface CNE1b-S of the second conductive layer CNE1b. Accordingly, the second connection portion CP2 of the first connection electrode CNE1 may have a tip portion due to a portion of the third conductive layer CNE1c protruding compared to the second conductive layer CNE1b. For example, based on the same etching process, when etching the second conductive layer CNE1b using an etching material having a high etch rate for the second conductive layer CNE1b compared to the first conductive layer CNE1a and the third conductive layer CNE1c, the first connection electrode CNE1 may be formed to have the tip portion.

The second via insulating layer VIA2 may define a second-first sub-opening OP2a that exposes a portion of the first connection electrode CNE1. For example, the second-first sub-opening OP2a may expose the tip portion of the second connection portion CP2 of the first connection electrode CNE1.

The pixel defining layer PDL may define a second-second sub-opening OP2b corresponding to the second-first sub-opening OP2a. The second-second sub-opening OP2b may be located on the second-first sub-opening OP2a, and the second-first sub-opening OP2a and the second-second sub-opening OP2b may be spatially connected to each other. For example, the second-first sub-opening OP2a and the second-second sub-opening OP2b may be spatially connected to define a second opening OP2, and the second opening OP2 may expose the tip portion of the second connection portion CP2 of the first connection electrode CNE1.

The lower functional layer, the upper functional layer, and the cathode electrode layer CEL may also be separated (or disconnected) by the tip portion of the second connection portion CP2 of the first connection electrode CNE1. Because the lower functional layer and the upper functional layer are separated (or disconnected) by the tip portion of the second connection portion CP2 of the first connection electrode CNE1, the lower functional layer and the upper functional layer may expose at least a portion of the side surface CNE1b-S of the second conductive layer CNE1b of the first connection electrode CNE1. Accordingly, the first-second cathode electrode CE1-2 (or the first-third cathode electrode CE1-3) may contact the side surface CNE1b-S of the second conductive layer CNE1b of the first connection electrode CNE1.

The first-second cathode electrode CE1-2 (or the first-third cathode electrode CE1-3) may be electrically connected to the corresponding first connection electrode CNE1. For example, the first-second cathode electrode CE1-2 (or the first-third cathode electrode CE1-3) may contact the side surface CNE1b-S of the second conductive layer CNE1b of the first connection electrode CNE1. For example, in case that a deposition angle of a deposition process for forming the cathode electrode layer CEL is greater than a deposition angle of a deposition process for forming the lower functional layer and a deposition angle of a deposition process for forming the upper functional layer, the cathode electrode layer CEL (e.g., the first-second cathode electrode CE1-2 or the first-third cathode electrode CE1-3) may be formed to overlap the discontinuity in the lower functional layer (e.g., the first lower functional layer BL1) and the discontinuity in the upper functional layer (e.g., the first upper functional layer UL1) separated by the tip portion and to contact the side surface CNE1b-S of the second conductive layer CNE1b of the first connection electrode CNE1. For example, the first-second cathode electrode CE1-2 (or the first-third cathode electrode CE1-3) may directly contact the first connection electrode CNE1. Accordingly, the first-second cathode electrode CE1-2 (or the first-third cathode electrode CE1-3) may be electrically connected to the first connection electrode CNE1.

In an embodiment, the first connection electrode CNE1 may be electrically connected to the first horizontal power transmission line HSL1 through a second bridge electrode BRE2. As illustrated in FIG. 10, the second bridge electrode BRE2 may overlap each of the first horizontal power transmission line HSL1 and the first connection electrode CNE1 in a plan view.

In an embodiment, the second bridge electrode BRE2 may be disposed on the same layer as the first and second contact electrodes SE and DE of FIG. 7. The second bridge electrode BRE2 may contact the first horizontal power transmission line HSL1 through a second contact hole CNT2 that penetrates the first to fourth insulating layers IL1, IL2, IL3, and IL4. The first connection electrode CNE1 may contact the second bridge electrode BRE2 through a second via hole VH1 that penetrates the first via insulating layer VIA1. However, this is an example and the present invention is not necessarily limited thereto.

Accordingly, the first-second cathode electrode CE1-2 (or the first-third cathode electrode CE1-3) may be electrically connected to the first horizontal power transmission line HSL1 through the first connection electrode CNE1 and the second bridge electrode BRE2. Therefore, the first-second cathode electrode CE1-2 (or the first-third cathode electrode CE1-3) may receive the first low power voltage through the first horizontal power transmission line HSL1.

In an embodiment, as illustrated in FIG. 4, the first-second cathode electrode CE1-2 (or the first-third cathode electrode CE1-3) may be electrically connected to two or more second connection portions CP2. Accordingly, it is possible to reduce defects (e.g., dark spots, luminance degradation, or the like) of the first light emitting element LDa due to poor connection between the first-second cathode electrode CE1-2 (or the first-third cathode electrode CE1-3) and the first horizontal power transmission line HSL1.

FIG. 12 is an enlarged plan view illustrating an area around a third connection portion of the display device of FIG. 4. FIG. 13 is a cross-sectional view taken along line IV-IV’ of FIG. 12.

Hereinafter, an example of the connection structure of the second cathode electrode CE2, the second vertical power transmission line VSL2, and the second horizontal power transmission line HSL2 will be described in detail. with reference to FIGS. 10 and 11.

Referring to FIGS. 4, 12 and 13, in an embodiment, the second cathode electrode2 CE2 may be electrically connected to a third connection portion CP3 of the corresponding second vertical power transmission line VSL2.

In an embodiment, the second vertical power transmission line VSL2 may have a multi-layer structure in which a plurality of conductive layers are stacked. For example, the second vertical power transmission line VSL2 may include a first conductive layer VSL2a, a second conductive layer VSL2b, and a third conductive layer VSL2c that are sequentially stacked. For example, the second vertical power transmission line VSL2 may have substantially the same layer structure as the first vertical power transmission line VSL1 described above with reference to FIGS. 8 and 9. Therefore, repeated description will be omitted or simplified.

A side surface VSL2b-S of the second conductive layer VSL2b may be recessed in a direction toward a center of the second vertical power transmission line VSL2 from a side surface VSL2a-S of the first conductive layer VSL2a and a side surface VSL2c-S of the third conductive layer VSL2c. For example, the side surface VSL2a-S of the first conductive layer VSL2a and the side surface VSL2c-S of the third conductive layer VSL2c may protrude outward from the side surface VSL2b-S of the second conductive layer VSL2b. Accordingly, the third connection portion CP3 of the second vertical power transmission line VSL2 may have a tip portion due to a portion of the third conductive layer VSL2c protruding compared to the second conductive layer VSL2b. For example, based on the same etching process, when etching the second conductive layer VSL2b using an etching material having a high etch rate for the second conductive layer VSL2b compared to the first conductive layer VSL2a and the third conductive layer VSL2c, the second vertical power transmission line VSL2 may be formed to have the tip portion.

The second via insulating layer VIA2 may define a third-first sub-opening OP3a that exposes a portion of the second vertical power transmission line VSL2. For example, the third-first sub-opening OP3a may expose the tip portion of the third connection portion CP3 of the second vertical power transmission line VSL2.

The pixel defining layer PDL may define a third-second sub-opening OP3b corresponding to the third-first sub-opening OP3a. The third-second sub-opening OP3b may be located on the third-first sub-opening OP3a, and the third-first sub-opening OP3a and the third-second sub-opening OP3b may be spatially connected to each other. For example, the third-first sub-opening OP3a and the third-second sub-opening OP3b may be spatially connected to define a third opening OP3, and the third opening OP3 may expose the tip portion of the third connection portion CP3 of the second vertical power transmission line VSL2.

The lower functional layer, the upper functional layer, and the cathode electrode layer CEL may also be separated (or disconnected) by the tip portion of the third connection portion CP3 of the second vertical power transmission line VSL2. Because the lower functional layer and the upper functional layer are separated (or disconnected) by the tip portion of the third connection portion CP3 of the second vertical power transmission line VSL2, the lower functional layer and the upper functional layer may expose at least a portion of the side surface VSL2b-S of the second conductive layer VSL2b of the second vertical power transmission line VSL2. Accordingly, the second cathode electrode CE2 may contact the side surface VSL2b-S of the second conductive layer VSL2b of the second vertical power transmission line VSL2.

The second cathode electrode CE2 may be electrically connected to the corresponding second vertical power transmission line VSL2. For example, the second cathode electrode CE2 may contact the side surface VSL2b-S of the second conductive layer VSL2b of the second vertical power transmission line VSL2. For example, in case that a deposition angle of a deposition process for forming the cathode electrode layer CEL is greater than a deposition angle of a deposition process for forming the lower functional layer and a deposition angle of a deposition process for forming the upper functional layer, the cathode electrode layer CEL (e.g., the second cathode electrode CE2) may be formed to overlap the discontinuity in the lower functional layer (e.g., the second lower functional layer BL2) and the discontinuity in the upper functional layer (e.g., the second upper functional layer UL2) separated by the tip portion and to contact the side surface VSL2b-S of the second conductive layer VSL2b of the second vertical power transmission line VSL2. For example, the second cathode electrode CE2 may directly contact the second vertical power transmission line VSL2. Accordingly, the second cathode electrode CE2 may be electrically connected to the second vertical power transmission line VSL2.

In an embodiment, the second vertical power transmission line VSL2 may be electrically connected to the second horizontal power transmission line HSL2 through a third bridge electrode BRE3. As illustrated in FIG. 12, the third bridge electrode BRE3 may be disposed at a crossing area where the second vertical power transmission line VSL2 and the second horizontal power transmission line HSL2 cross each other in a plan view.

In an embodiment, the third bridge electrode BRE3 may be disposed on the same layer as the first and second contact electrodes SE and DE of FIG. 7. The third bridge electrode BRE3 may contact the second horizontal power transmission line HSL2 through a third contact hole CNT3 that penetrates the first to fourth insulating layers IL1, IL2, IL3, and IL4. The second vertical power transmission line VSL2 may contact the third bridge electrode BRE3 through a third via hole VH3 that penetrates the first via insulating layer VIA1. However, this is an example and the present invention is not necessarily limited thereto.

Accordingly, the second cathode electrode CE2 may be electrically connected to the second vertical power transmission line VSL2 and the second horizontal power transmission line HSL2. Therefore, the second cathode electrode CE2 may receive the second low power voltage through the second vertical power transmission line VSL2 and the second horizontal power transmission line HSL2.

In an embodiment, as illustrated in FIG. 4, the second cathode electrode CE2 may be electrically connected to two or more third connection portions CP3. Accordingly, it is possible to reduce defects (e.g., dark spots, luminance degradation, or the like) of the second and third light emitting elements LDb and LDc due to poor connection between the second cathode electrode CE2 and the second vertical power transmission line VSL2.

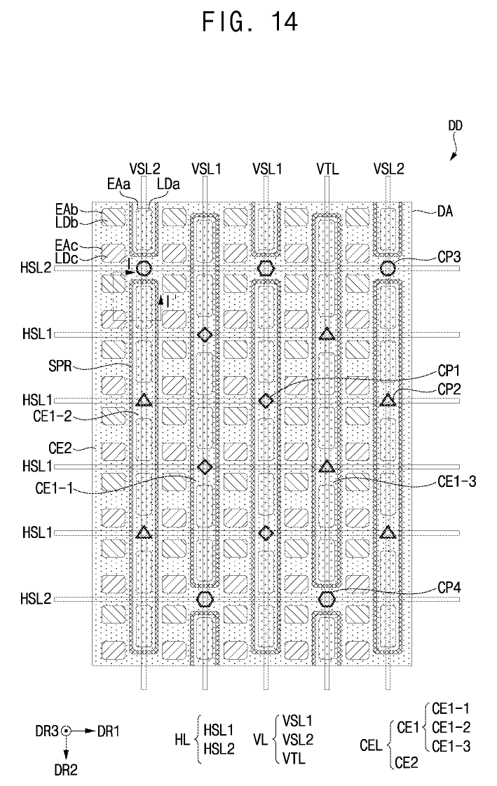

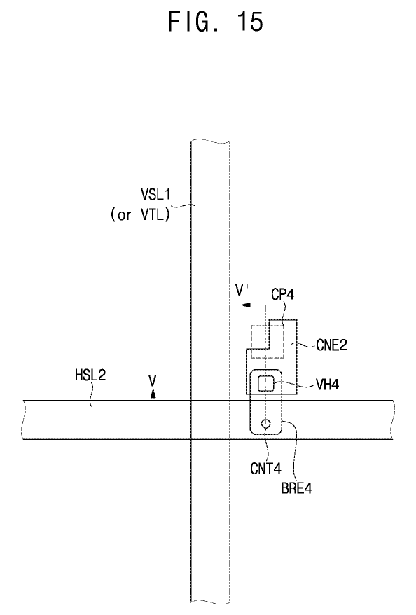

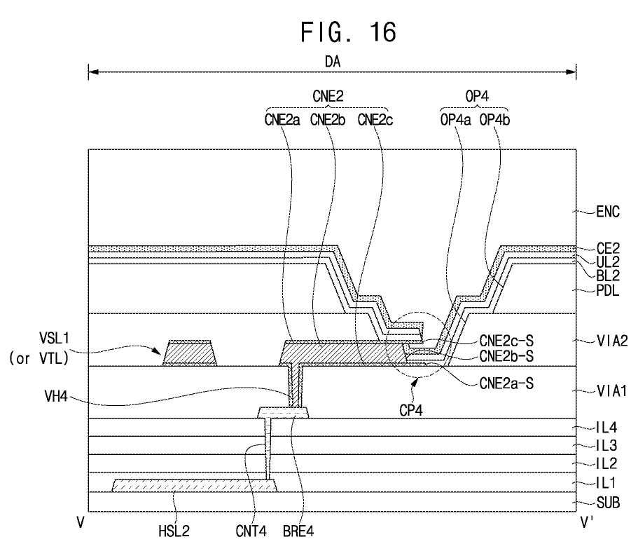

FIG. 14 is a plan view illustrating an example of the enlarged portion of the display device of FIG. 1. FIG. 10 is an enlarged plan view illustrating an area around a fourth connection portion of the display device of FIG. 14. FIG. 16 is a cross-sectional view taken along line V-V’ of FIG. 15.

Referring to FIGS. 14 to 16, in an embodiment, the second cathode electrode CE2 may be electrically connected to a fourth connection portion CP4 of a second connection electrode CNE2. The second cathode electrode CE2 may be electrically connected to the second horizontal power transmission line HSL2 through the second connection electrode CNE2.

In an embodiment, the second connection electrode CNE2 may be disposed in the same layer as the first vertical power transmission line VSL1 (or the voltage transmission line VTL). As illustrated in FIG. 15, in a plan view, the second connection electrode CNE2 may be adjacent to the first vertical power transmission line VSL1 (or the voltage transmission line VTL), and may be spaced apart from the first vertical power transmission line VSL1 (or the voltage transmission line VTL). The second connection electrode CNE2 may electrically connect the second horizontal power transmission line HSL2 and the second cathode electrode CE2. The second connection electrode CNE2 might not be electrically connected to the first vertical power transmission line VSL1 (or the voltage transmission line VTL).

In an embodiment, the second connection electrode CNE2 may have a multi-layer structure in which a plurality of conductive layers are stacked. For example, the second connection electrode CNE2 may include a first conductive layer CNE2a, a second conductive layer CNE2b, and a third conductive layer CNE2c that are sequentially stacked. For example, the second connection electrode CNE2 may have substantially the same layer structure as the first vertical power transmission line VSL1 described above with reference to FIGS. 8 and 9. Therefore, repeated description will be omitted or simplified.

A side surface CNE2b-S of the second conductive layer CNE2b may be recessed in a direction toward a center of the second connection electrode CNE2 from a side surface CNE2a-S of the first conductive layer CNE2a and a side surface CNE2c-S of the third conductive layer CNE2c. For example, the side surface CNE2a-S of the first conductive layer CNE2a and the side surface CNE2c-S of the third conductive layer CNE2c may protrude outward from the side surface CNE2b-S of the second conductive layer CNE2b. Accordingly, the fourth connection portion CP4 of the second connection electrode CNE2 may have a tip portion due to a portion of the third conductive layer CNE2c protruding compared to the second conductive layer CNE2b. For example, based on the same etching process, when etching the second conductive layer CNE2b using an etching material having a high etch rate for the second conductive layer CNE2b compared to the first conductive layer CNE2a and the third conductive layer CNE2c, the second connection electrode CNE2 may be formed to have the tip portion.

The second via insulating layer VIA2 may define a fourth-first sub-opening OP4a that exposes a portion of the second connection electrode CNE2. For example, the fourth-first sub-opening OP4a may expose the tip portion of the fourth connection portion CP4 of the second connection electrode CNE2.

The pixel defining layer PDL may define a fourth-second sub-opening OP4b corresponding to the fourth-first sub-opening OP4a. The fourth-second sub-opening OP4b may be located on the fourth-first sub-opening OP4a, and the fourth-first sub-opening OP4a and the fourth-second sub-opening OP4b may be spatially connected to each other. For example, the fourth-first sub-opening OP4a and the fourth-second sub-opening OP4b may be spatially connected to define a fourth opening OP4, and the fourth opening OP4 may expose the tip portion of the fourth connection portion CP4 of the second connection electrode CNE2.

The lower functional layer, the upper functional layer, and the cathode electrode layer CEL may also be separated (or disconnected) by the tip portion of the fourth connection portion CP4 of the second connection electrode CNE2. Because the lower functional layer and the upper functional layer are separated (or disconnected) by the tip portion of the fourth connection portion CP4 of the second connection electrode CNE2, the lower functional layer and the upper functional layer may expose at least a portion of the side surface CNE2b-S of the second conductive layer CNE2b of the second connection electrode CNE2. Accordingly, the second cathode electrode CE2 may contact the side surface CNE2b-S of the second conductive layer CNE2b of the second connection electrode CNE2.

The second cathode electrode CE2 may be electrically connected to the corresponding second connection electrode CNE2. For example, the second cathode electrode CE2 may contact the side surface CNE2b-S of the second conductive layer CNE2b of the second connection electrode CNE2. For example, in case that a deposition angle of a deposition process for forming the cathode electrode layer CEL is greater than a deposition angle of a deposition process for forming the lower functional layer and a deposition angle of a deposition process for forming the upper functional layer, the cathode electrode layer CEL (e.g., the second cathode electrode CE2) may be formed to overlap the discontinuity in the lower functional layer (e.g., the second lower functional layer BL2) and the discontinuity in the upper functional layer (e.g., the second upper functional layer UL2) separated by the tip portion and to contact the side surface CNE2b-S of the second conductive layer CNE2b of the second connection electrode CNE2. For example, the second cathode electrode CE2 may directly contact the second connection electrode CNE2. Accordingly, the second cathode electrode CE2 may be electrically connected to the second connection electrode CNE2.

In an embodiment, the second connection electrode CNE2 may be electrically connected to the second horizontal power transmission line HSL2 through a fourth bridge electrode BRE4. As illustrated in FIG. 15, the fourth bridge electrode BRE4 may overlap each of the second horizontal power transmission line HSL2 and the second connection electrode CNE2 in a plan view.

In an embodiment, the fourth bridge electrode BRE4 may be disposed on the same layer as the first and second contact electrodes SE and DE of FIG. 7. The fourth bridge electrode BRE4 may contact the second horizontal power transmission line HSL2 through a fourth contact hole CNT4 that penetrates the first to fourth insulating layers IL1, IL2, IL3, and IL4. The second connection electrode CNE2 may contact the fourth bridge electrode BRE4 through a fourth via hole VH4 that penetrates the first via insulating layer VIA1. However, this is an example and the present invention is not necessarily limited thereto.

Accordingly, the second cathode electrode CE2 may be electrically connected to the second horizontal power transmission line HSL2 through the second connection electrode CNE2 and the fourth bridge electrode BRE4. In addition, compared to embodiment of FIG. 4, the second cathode electrode CE2 may be further directly connected to the second connection electrode CNE2, which is electrically connected to the second horizontal power transmission line HSL2. Therefore, it is possible to further reduce defects (e.g., dark spots, luminance degradation, or the like) of the second and third light emitting elements LDb and LDc due to poor connection between the second cathode electrode CE2 and the second vertical power transmission line VSL2.

The display device according to embodiments described above may be applied to various electronic devices.

Thus, in the connection structures that deliver low power voltages to different cathode electrodes in an OLED display, each cathode electrode, such as CE1-1 for blue pixels or CE2 for red and green pixels, is connected to vertical and horizontal power transmission lines through multi-layer connection electrodes and bridge electrodes, which ensure reliable electrical contact despite complex layer stacking and insulating structures. These connections are designed to maintain stable voltage delivery while minimizing defects like dark spots, enabling efficient power distribution for color-specific driving requirements.

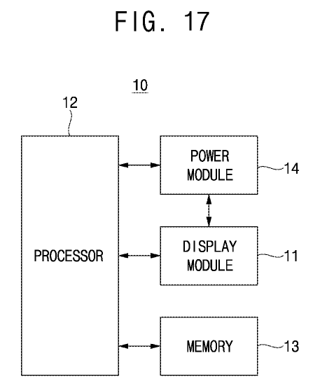

FIG. 17 is a block diagram illustrating an electronic device according to an embodiment.

Referring to FIG. 17, an electronic device 10, according to an embodiment, may include a display module 11, a processor 12, a memory 13, and a power module 14.

In an embodiment, the electronic device 10 may include the display device DD of FIGS. 1 to 16. In an embodiment, the electronic device 10 may further include modules or devices with additional functions other than the display device.

The processor 12 may include at least one of a central processing unit (“CPU”), an application processor (“AP”), a graphic processing unit (“GPU”), a communication processor (“CP”), an image signal processor (“ISP”), and a controller.

In an embodiment, the processor 12 may be configured to provide an image data signal and/or an input control signal to the display device.

The memory 13 may store data information necessary for the operation of the processor 12 or the display module 11. When the processor 12 executes the application stored in the memory 13, the image data signal and/or the input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

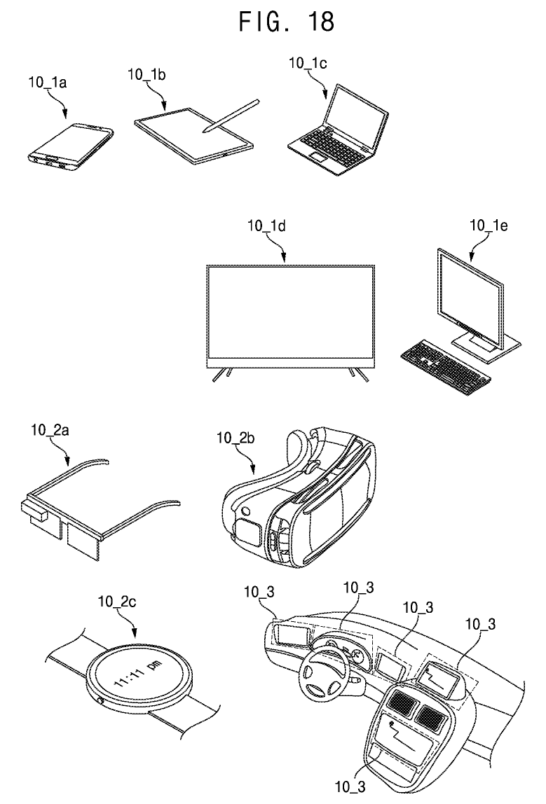

FIG. 18 is a schematic diagram illustrating electronic devices according to various embodiments.

Referring to FIGS. 17 and 18, various electronic devices 10 to which the display device according to embodiments are applied may include not only image display electronic devices such as a smartphone 10_1a, a tablet computer 10_1b, a laptop/notebook computer 10_1c, a TV 10_1d, and a computer monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (“CID”) disposed on a dashboard, and a room mirror display, or the like. The electronic device 10 is not necessarily limited to the image display electronic devices, the wearable electronic devices, and the automotive electronic devices.

Although embodiments and implementations have been described herein, other embodiments and modifications will be apparent from this description. Accordingly, the invention is not necessarily limited to such embodiments, but rather to the broader scope of the appended claims and various obvious modifications and equivalent arrangements as would be apparent to a person of ordinary skill in the art.

What is claimed is:

1. A display device, comprising:
a substrate including a first emission area and a second emission area;
a first pixel circuit and a second pixel circuit disposed on the substrate;
a first light emitting element disposed in the first emission area of the substrate and including:
a first anode electrode electrically connected to the first pixel circuit;
a first emission layer disposed on the first anode electrode; and
a first cathode electrode disposed on the first emission layer and to which a first low power voltage is applied;
a second light emitting element disposed in the second emission area of the substrate and including:
a second anode electrode spaced apart from the first anode electrode and electrically connected to the second pixel circuit;
a second emission layer disposed on the second anode electrode; and
a second cathode electrode disposed on the second emission layer, spaced apart from the first cathode electrode, and to which a second low power voltage is applied; and
a separator disposed between the first cathode electrode and the second cathode electrode.

2. The display device of claim 1, wherein the first cathode electrode and the second cathode electrode are electrically insulated from each other.

3. The display device of claim 1, wherein the second low power voltage has a voltage level that is different from the first low power voltage.

4. The display device of claim 3, wherein a same high power voltage is applied to the first pixel circuit and the second pixel circuit.

5. The display device of claim 1, further comprising:
a third pixel circuit disposed on the substrate; and
a third light emitting element disposed in a third emission area of the substrate and including:
a third anode electrode spaced apart from each of the first anode electrode and the second anode electrode and electrically connected to the third pixel circuit;
a third emission layer disposed on the third anode electrode; and
the second cathode electrode,
wherein a first portion of the second cathode electrode is disposed on the second emission layer, and a second portion of the second cathode electrode is disposed on the third emission layer.

6. The display device of claim 5, wherein the first light emitting element emits blue light, the second light emitting element emits red light, and the third light emitting element emits green light.

7. The display device of claim 1, wherein each of the first emission area and the second emission area is provided in plurality,
wherein the first cathode electrode is provided in plurality, and
wherein, in a plan view, the second cathode electrode is spaced apart from the plurality of first cathode electrodes and surrounds the plurality of first cathode electrodes.

8. The display device of claim 7, wherein, in the plan view, each of the first cathode electrodes of the plurality of first cathode electrodes overlap two or more first emission areas of the plurality of first emission areas, and
wherein, in the plan view, the second cathode electrode overlaps all of the second emission areas of the plurality of second emission areas.

9. The display device of claim 8, wherein, in the plan view, each of the first cathode electrodes of the plurality of cathode electrodes is spaced apart from the plurality of second emission areas, and
wherein, in the plan view, the second cathode electrode is spaced apart from the plurality of first emission areas.

10. The display device of claim 7, wherein the separator is provided in plurality, and
wherein, in the plan view, each of the plurality of separators surrounds two or more first emission areas of the plurality of first emission areas.

11. The display device of claim 7, further comprising:
vertical transmission lines spaced apart from each other in a first direction and each extending in a second direction crossing the first direction; and
horizontal transmission lines disposed in a different layer from that of the vertical transmission lines, spaced apart from each other in the second direction, and each extending in the first direction,
wherein the horizontal transmission lines include:
a first horizontal power transmission line to which the first low power voltage is applied; and
a second horizontal power transmission line that is spaced apart from the first horizontal power transmission line and to which the second low power voltage is applied, and
wherein the vertical transmission lines include:
a first vertical power transmission line electrically connected to the first horizontal power transmission line and transmitting the first low power voltage to the plurality of first cathode electrodes; and
a second vertical power transmission line spaced apart from the first vertical power transmission line, electrically connected to the second horizontal power transmission line, and transmitting the second low power voltage to the second cathode electrode.

12. The display device of claim 11, wherein the plurality of first cathode electrodes include:
a first-first cathode electrode corresponding to the first vertical power transmission line; and
a first-second cathode electrode corresponding to the second vertical power transmission line,
wherein the first-first cathode electrode is electrically connected to the first vertical power transmission line, and
wherein the first-second cathode electrode is electrically connected to the first horizontal power transmission line.

13. The display device of claim 12, wherein the first-first cathode electrode directly contacts the first vertical power transmission line.

14. The display device of claim 12, further comprising:
a first connection electrode disposed on a same layer as that of the second vertical power transmission line, the first connection electrode being adjacent to the second vertical power transmission line and spaced apart from the second vertical power transmission line in the plan view, the first connection electrode electrically connecting the first horizontal power transmission line and the first-second cathode electrode to one another.

15. The display device of claim 14, wherein the first-second cathode electrode directly contacts the first connection electrode.

16. The display device of claim 11, wherein the second cathode electrode directly contacts the second vertical power transmission line.

17. The display device of claim 11, further comprising:
a second connection electrode disposed on a same layer as that of the first vertical power transmission line, the second connection electrode being adjacent to the first vertical power transmission line and spaced apart from the first vertical power transmission line in the plan view, the second connection electrode electrically connecting the second horizontal power transmission line and the second cathode electrode to one another.

18. The display device of claim 17, wherein the second cathode electrode directly contacts the second connection electrode.

19. A display device, comprising:
a substrate including first emission areas emitting light of a first color, second emission areas emitting light of a second color, and third emission areas emitting light of a third color;
a first cathode electrode disposed on the substrate, the first cathode electrode overlapping two or more first emission areas of the first emission areas and spaced apart from the second emission areas and the third emission areas in a plan view, a first low power voltage being applied to the first cathode electrode;
a second cathode electrode disposed on the substrate, the second cathode electrode overlapping all of the second emission areas and all of the third emission areas and spaced apart from the first emission areas in the plan view, the second cathode electrode being spaced apart from the first cathode electrode and surrounding the first cathode electrode in the plan view, a second low power voltage having a different voltage level from the first low power voltage being applied to the second cathode electrode; and
a separator disposed between the first cathode electrode and the second cathode electrode, the separator surrounding the first cathode electrode in the plan view.

20. An electronic device, comprising:
a display device including light emitting elements; and
a processor configured to transmit an image data signal and an input control signal to the display device,
wherein the display device includes:
a substrate including a first emission area and a second emission area;
a first pixel circuit and a second pixel circuit disposed on the substrate;
a first light emitting element disposed in the first emission area of the substrate and including:
a first anode electrode electrically connected to the first pixel circuit;
a first emission layer disposed on the first anode electrode; and
a first cathode electrode disposed on the first emission layer and to which a first low power voltage is applied;
a second light emitting element disposed in the second emission area of the substrate and including:
a second anode electrode spaced apart from the first anode electrode and electrically connected to the second pixel circuit;
a second emission layer disposed on the second anode electrode; and
a second cathode electrode disposed on the second emission layer, spaced apart from the first cathode electrode, and to which a second low power voltage is applied; and
a separator disposed between the first cathode electrode and the second cathode electrode.
